(19) United States
(12) Patent Application Publication
(10) Pub. No.: US 2024/0130219 A1
(43) Pub. Date: Apr. 18, 2024

(54) ORGANIC ELECTROLUMINESCENT DEVICE AND APPLICATION THEREOF

(71) Applicant: BEIJING SUMMER SPROUT TECHNOLOGY CO., LTD., Beijing (CN)

(72) Inventors: Zhen Wang, Beijing (CN); Hongbo Li, Beijing (CN); Wei Cai, Beijing (CN); Zheng Wang, Beijing (CN); Jing Wang, Beijing (CN); Ying Hou, Beijing (CN); Chi Yuen Raymond Kwong, Beijing (CN); Chuanjun Xia, Beijing (CN)

(73) Assignee: BEIJING SUMMER SPROUT TECHNOLOGY CO., LTD., Beijing (CN)

(21) Appl. No.: 18/371,745

(22) Filed: Sep. 22, 2023

(30) Foreign Application Priority Data
Sep. 23, 2022 (CN) 202211149900.3
Mar. 22, 2023 (CN) 202310281726.6

(51) Int. Cl. H10K 85/30; C07F 15/00; C09K 11/02; C09K 11/06

(52) U.S. Cl. CPC H10K 85/342; C07F 15/0033; C09K 11/02; C09K 11/06; H10K 50/11

(57) ABSTRACT

Provided is an organic electroluminescent device and an application thereof. The organic electroluminescent device includes a metal complex having a substituent A capable of reducing a maximum capacitance in the device, and the metal complex can be used as an emissive material in an emissive layer of the electroluminescent device. The device including a metal complex having the substituent A can obtain a decrease in the maximum capacitance of the device, thereby improving the response time and refresh frequency of an OLED display device at a low grayscale. In another aspect, the substituent A can cause a decrease in the maximum capacitance of the device, and the device prepared with the metal complex including the substituent A can still maintain excellent device performance compared with the devices prepared with the metal complexes that do not include the substituent A. Further provided is an electronic assembly including the organic electroluminescent device.

### CROSS-REFERENCE TO RELATED APPLICATION(S))

This application claims priority to Chinese Patent Application No. 20221149900.3 filed on Sep. 23, 2022 and Chinese Patent Application No. 202310281726.6 filed on Mar. 22, 2023, the disclosure of which are incorporated herein by reference in their entireties.

### TECHNICAL FIELD

The present disclosure relates to organic electronic devices, for example, organic electroluminescent devices. In particular, the present disclosure relates to an organic electroluminescent device including a metal complex having a substituent A capable of reducing a maximum capacitance in the device, a display assembly including the organic electroluminescent device, and an application of the metal complex in organic optoelectronic devices.

### BACKGROUND

Organic electronic devices include, but are not limited to, the following types: organic light-emitting diodes (OLEDs), organic field-effect transistors (O-FETs), manic light-emitting transistors (OLETs), organic photovoltaic devices (OPVs), dye-sensitized solar cells (DSSCs), organic optical detectors, organic photoreceptors, organic field-quench devices (OFQDs), light-emitting electrochemical cells (LECs), organic laser diodes and organic plasmon emitting devices.

In 1987, Tang and Van Slyke of Eastman Kodak reported a bilayer organic electroluminescent device, which includes an arylamine hole transporting layer and a tris-8-hydroxyquinolato-aluminum layer as the electron and emitting layer (Applied Physics Letters, 1987, 51 (12): 913-915). Once a bias is applied to the device, green light was emitted from the device. This device laid the foundation for the development of modern organic light-emitting diodes (OLEDs), State-of-the-art OLEDs may include multiple layers such as charge injection and transporting layers, charge and exciton blocking layers, and one or multiple emissive layers between the cathode and anode. Since the OLED is a self-emitting solid state device, it offers tremendous potential for display and lighting applications. In addition, the inherent properties of organic materials, such as their flexibility, may make them well suited for particular applications such as fabrication on flexible substrates.

The OLED can be categorized as three different types according to its emitting mechanism. The OLED invented by Tang and van Slyke is a fluorescent OLED. It only utilizes singlet emission. The triplets generated in the device are wasted through nonradiative decay channels. Therefore, the internal quantum efficiency (IQE) of the fluorescent OLED is only 25%. This limitation hindered the commercialization of OLED. In 1997, Forrest and Thompson reported phosphorescent OLED, which uses triplet emission from heavy metal containing complexes as the emitter. As a result, both singlet and triplets can be harvested, achieving 100% IQE. The discovery and development of phosphorescent OLED contributed directly to the commercialization of active-matrix OLED (AMOLED) due to its high efficiency. Recently, Adachi achieved high efficiency through thermally activated delayed fluorescence (TADF) of organic compounds. These emitters have small singlet-triplet gap that makes the transition from triplet back to singlet possible. In the TADF device, the triplet excitons can go through reverse intersystem crossing to generate singlet excitons, resulting in high IQE.

OLEDs can also be classified as small molecule and polymer OLEDs according to the forms of the materials used. A small molecule refers to any organic or organometallic material that is not a polymer. The molecular weight of the small molecule can be large as long as it has well defined structure. Dendrimers with well-defined structures are considered as small molecules. Polymer OLEDs include conjugated polymers and non-conjugated polymers with pendant emitting groups. Small molecule OLED can become the polymer OLED if post polymerization occurred during the fabrication process.

There are various methods for OLED fabrication. Small molecule OLEDs are generally fabricated by vacuum thermal evaporation. Polymer OLEDs are fabricated by solution process such as spin-coating, inkjet printing, and slit printing. If the material can be dissolved or dispersed in a solvent, the small molecule OLED can also be produced by solution process.

The emitting color of the OILED can be achieved by emitter structural design. An OLED may include one emitting layer or a plurality of emitting layers to achieve desired spectrum. In the case of green, yellow, and red OLEDs, phosphorescent emitters have successfully reached commercialization. Blue phosphorescent device still suffers from non-saturated blue color, short device lifetime, and high operating voltage. Commercial full-color OLED displays normally adopt a hybrid strategy, using fluorescent blue and phosphorescent yellow, or red and green. At present, efficiency roll-off of phosphorescent OLEDs at high brightness remains a problem. In addition, it is desirable to have more saturated emitting color, higher efficiency, and longer device lifetime.

From the perspective of electronics, the display principle of the OLED is briefly explained as follows: under the action of an applied electric field greater than a certain threshold, holes and electrons are injected into an organic thin-film emissive layer sandwiched between the anode and the cathode, respectively, in the form of an electric current, the holes and electrons recombine to form excitons, and radiation recombination occurs to cause light emission. Since the organic emissive thin film has significant capacitance characteristics, the capacitance of the organic thin-film emissive layer is a key factor affecting the response time and refresh frequency of an OLED display device at a low grayscale.

In an OLED device, the movement, distribution, and accumulation of charges in the device can be analyzed by studying the C-V (capacitance-voltage) characteristics of the device. As shown in FIG. 3 which is an example curve graph of the capacitance-voltage (C-V) characteristic of a device, the kinetic study of the charge in the device can be roughly divided into the following four cases, depending on the applied bias voltages.
1) When the applied voltage V₀ is less than the initial voltage Vₜ, that is, V₀<Vₜ, the carriers (holes) cannot enter the interior of the device, and the device acts like an insulator connected between the cathode and the anode. Therefore, in this case, the capacitance of the device is a constant, and the capacitance in this case is referred to as the geometric capacitance C_{geo} of the device.
2) When the applied voltage V₀ is greater than the initial voltage Vₜ but is less than the voltage V_{Cmax} that is, Vₜ<V₀<V_{Cmax}, the holes start to be injected, into the interior of the device, and as the holes accumulate inside the device, the capacitance of the device gradually increases.
3) When the applied voltage V₀ continuously increases, the capacitance value of the device also continuously increases in this case until the applied voltage V₀ is equal to the voltage V_{Cmax} of the device, that is, V₀=V_{Cmax}, and the capacitance of the device reaches the maximum value Cₘₐₓ.
4) When the applied voltage V₀ is greater than the voltage V_{Cmax}, V₀>that is, V_{Cmax} electrons start to be injected into the interior of the device, then the hole-electron recombination process occurs, and as the carriers accumulated in the device are consumed, the capacitance of the device gradually decreases.

The magnitude of the capacitance of the device is affected by the injection and transport of charges from the materials in the organic thin-film emissive layer. Some studies have shown that the capacitance of the device can be reduced by reducing the injection of holes. However, such a method may affect the charge balance inside the device, thereby affecting the efficiency and lifetime of the device. Currently, there is no relevant study reported on how to achieve a low-capacitance OLED device by changing the structure of the materials in the emissive layer, and in particular, no study on the effect of the structure of an emissive material in the emissive layer on the capacitance of the device is reported, because the weight ratio of the emissive material in the emissive layer of the device is relatively small.

### SUMMARY

The present disclosure aims to provide a series of organic electroluminescent devices including a metal complex having a substituent A capable of reducing the maximum capacitance in the device to at least solve part of the problems described above. The metal complex can be used as an emissive material in electroluminescent devices. The device including the metal complex having the substituent A can obtain a decrease in the maximum capacitance of the device, thereby improving the response time and refresh frequency of an OLED display device at a low grayscale. In another aspect, in addition to the decrease in the maximum capacitance of the device caused by the substituent A, the device prepared with the metal complex including the substituent A can still maintain excellent device performance compared with the devices prepared with the metal complexes that do not include the substituent A.

According, to an embodiment of the present disclosure, an organic electroluminescent device is disclosed;
the organic electroluminescent device includes a cathode, an anode, and an organic layer disposed between the cathode and the anode;
wherein the organic layer includes a metal complex, and the metal complex includes a metal M and at least one C\hat{ }N bidentate ligand Lₐ coordinated to the metal M;
the metal M is selected from a metal with a relative atomic mass greater than 40;
when two or more ligands Lₐ are present at the same time, the two or more ligands Lₐ may be identical or different;
at least one ligand Lₐ includes at least one substituent A;
the substituent A is, at each occurrence identically or differently, selected from a substituted or unsubstituted non-aromatic group having 1 to 20 carbon atoms;
when two or more substituents A are present at the same time, the) or more substituents A may be identical or different; and
the capacitance characteristics of the metal complex in an electroluminescent device satisfy:
at 500 Hz, a maximum capacitance of the electroluminescent device is Cₘₐₓ; and
at 500 Hz, a change in the maximum capacitance caused by the substituent A is ΔCₘₐₓ≤−0.12 nF.

According to an embodiment of the present disclosure, a display assembly is further disclosed. The display assembly includes the organic electroluminescent device described in the preceding embodiment.

The organic electroluminescent device adopts a metal complex having a substituent A capable of reducing the maximum capacitance in the device, and the organic electroluminescent device can improve the response time and refresh frequency of an OLED display device at a low grayscale and maintain excellent device performance.

### BRIEF DESCRIPTION OF DRAWINGS

FIG. 1 is a schematic diagram of an organic electroluminescent device disclosed by the present disclosure.

FIG. 2 is a schematic diagram of another organic electroluminescent device disclosed by the present disclosure.

FIG. 3 is an example curve graph of the capacitance-voltage (C-V) characteristic of a device.

### DETAILED DESCRIPTION

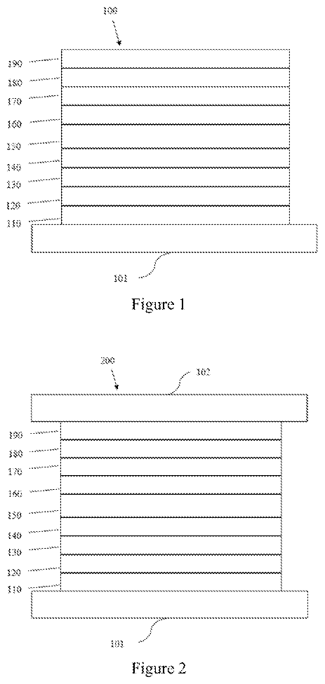

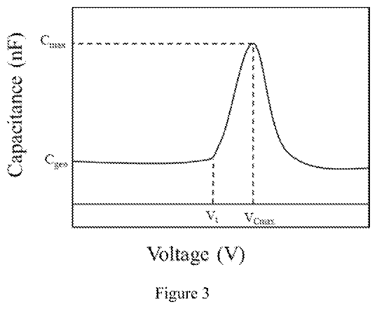

OLEDs can be fabricated on various types of substrates such as glass, plastic, and metal foil. FIG. 1 schematically shows an organic light-emitting device 100 without limitation. The figures are not necessarily drawn to scale. Some of the layers in the figures can also be omitted as needed. Device 100 may include a substrate 101, an anode 110, a hole injection layer 120, a hole transport layer 130, an electron blocking layer 140, an emissive layer 150, a hole blocking layer 160, an electron transport layer 170, an electron injection layer 180 and a cathode 190. Device 100 may be fabricated by depositing the layers described in order. The properties and functions of these various layers, as well as example materials, are described in more detail in U.S. Pat. No. 7,279,704 at cols. 6-10, the contents of which are incorporated by reference herein in its entirety.

More examples for each of these layers are available. For example, a flexible and transparent substrate-anode combination is disclosed in U.S. Pat. No. 5,844,363, which is incorporated by reference herein in its entirety. An example of a p-doped hole transport layer is m-MTDATA doped with F4-TCNQ at a molar ratio of 50:1, as disclosed in U.S. Patent Application Publication No. 2003/0230980, which is incorporated by reference herein in its entirety. Examples of host materials are disclosed in U.S. Pat. No. 6,303,238 to Thompson et al., which is incorporated by reference herein in its entirety. An example of an n-doped electron transport layer is BPhen doped with Li at a molar ratio of 1:1 as disclosed in U.S. Patent Application Publication No. 2003/0230980, which is incorporated by reference herein in its entirety. U.S. Pat. Nos. 5,703,436 and 5,707,745, which are incorporated by reference herein their entireties, disclose examples of cathodes including composite cathodes having a thin layer of metal such as Mg:Ag with an overlying transparent, electrically-conductive, sputter-deposited 110 layer. The theory and use of blocking layers are described in more detail in U.S. Pat. No. 6,097,147 and U.S. Patent Application Publication No. 2003/0230980, which are incorporated by reference herein in their entireties. Examples of injection layers are provided in U.S. Patent Application Publication No. 2004/0174116, which is incorporated by reference herein in its entirety. A description of protective layers may be found in U.S. Patent Application Publication No. 2004/0174116, which is incorporated by reference herein in its entirety.

The layered structure described above is provided by way of non-limiting examples. Functional OLEDs may be achieved by combining the various layers described in different ways, or layers may be omitted entirely. It may also include other layers not specifically described. Within each layer, a single material or a mixture of multiple materials can be used to achieve optimum performance. Any functional layer may include several sublayers. For example, the emissive layer may have two layers of different emitting materials to achieve desired emission spectrum.

In one embodiment, an OLED may be described as having an “organic layer” disposed between a cathode and an anode. This organic layer may include a single layer or multiple layers.

An OLED can be encapsulated by a barrier layer. FIG. 2 schematically shows an organic light emitting device 200 without limitation. FIG. 2 differs from FIG. 1 in that the organic light emitting device include a barrier layer 102, which is above the cathode 190, to protect it from harmful species from the environment such as moisture and oxygen. Any material that can provide the barrier function can be used as the barrier layer such as glass or organic-inorganic hybrid layers. The barrier layer should be placed directly or indirectly outside of the OLED device. Multilayer thin film encapsulation was described in U.S. Pat. No. 7,968,146, which is incorporated by reference herein in its entirety.

Devices fabricated in accordance with embodiments of the present disclosure can be incorporated into a wide variety of consumer products that have one or more of the electronic component modules (or units) incorporated therein. Some examples of such consumer products include flat panel displays, monitors, medical monitors, televisions, billboards, lights for interior or exterior illumination and/or signaling, heads-up displays, fully or partially transparent displays, flexible displays, smart phones, tablets, phablets, wearable devices, smart watches, laptop computers, digital cameras, camcorders, viewfinders, micro-displays, 3-D displays, vehicles displays, and vehicle tail lights.

The materials and structures described herein may be used in other organic electronic devices listed above.

As used herein, “top” means furthest away from the substrate, while “bottom” means closest to the substrate. Where a first layer is described as “disposed over” a second layer, the first layer is disposed further away from the substrate. There may be other layers between the first and second layers, unless it is specified that the first layer is “in contact with” the second layer. For example, a cathode may be described as “disposed over” an anode, even though there are various organic layers in between.

As used herein, “emission area” means the area of an organic electroluminescent device in the direction perpendicular to the emissive surface where the anode is in direct contact with the organic layer and at the same time the organic layer is in direct contact with the cathode. Herein, the emission area in examples and comparative examples is 0.04 cm².

As used herein, “solution processible” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

It is believed that the internal quantum efficiency (IQE) of fluorescent OLEDs can exceed the 25% spin statistics limit through delayed fluorescence. As used herein, there are two types of delayed fluorescence, i.e. P-type delayed fluorescence and E-type delayed fluorescence. P-type delayed fluorescence is generated from triplet-triplet annihilation (TTA).

On the other hand, E-type delayed fluorescence does not rely on the collision of two triplets, but rather on the transition between the triplet states and the singlet excited states. Compounds that are capable of generating E-type delayed fluorescence are required to have very small singlet-triplet gaps to convert between energy states. Thermal energy can activate the transition from the triplet state back to the singlet state. This type of delayed fluorescence is also known as thermally activated delayed fluorescence (TADF). A distinctive feature of TADF is that the delayed component increases as temperature rises. If the reverse intersystem crossing (RISC) rate is fast enough to minimize the non-radiative decay from the triplet state, the fraction of back populated singlet excited states can potentially reach 75%. The total singlet fraction can be 100%, far exceeding 25% of the spin statistics limit for electrically generated excitons.

E-type delayed fluorescence characteristics can be found in an exciplex system or in a single compound. Without being bound by theory, it is believed that E-type delayed fluorescence requires the luminescent material to have a small singlet-triplet energy gap (ΔE_{S-T}). Organic, non-metal containing, donor-acceptor luminescent materials may be able to achieve this. The emission in these materials is generally characterized as a donor-acceptor charge-transfer (CT) type emission. The spatial separation of the HOMO and LUMO in these donor-acceptor type compounds generally results in small ΔE_{S-T}. These states may involve CT states. Generally, donor-acceptor luminescent materials are constructed by connecting an electron donor moiety such as amino- or carbazole-derivatives and an electron acceptor moiety such as N-containing six-membered aromatic rings.

### Definition of Terms of Substituents

Halogen or halide—as used herein includes fluorine, chlorine, bromine, and iodine.

Alkyl—as used herein includes both straight and branched chain alkyl groups. Alkyl may be alkyl having 1 to 20 carbon atoms, preferably alkyl having 1 to 12 carbon atoms, and more preferably alkyl having 1 to 6 carbon atoms. Examples of alkyl groups include a methyl group, an ethyl group, a propyl group, an isopropyl group, an n-butyl group, an s-butyl group, an isobutyl group, a t-butyl group, an n-pentyl group, an n-hexyl group, an n-heptyl group, an n-octyl group, an n-nonyl group, an n-decyl group, an n-undecyl group, an n-dodecyl group, an n-tridecyl group, an n-tetradecyl group, an n-pentadecyl group, an n-hexadecyl group, an n-heptadecyl group, an n-octadecyl group, a neopentyl group, a 1-methylpentyl group, a 2-methylpentyl group, a 1-pentylhexyl group, a 1-butylpentyl group, a 1-heptyloctyl group, and a 3-methylpentyl group. Of the above, preferred are a methyl group, an ethyl group, a propyl group, an isopropyl group, a n-butyl group, an s-butyl group, an isobutyl group, a t-butyl group, an n-pentyl group, a neopentyl group, and an n-hexyl group. Additionally, the alkyl group may be optionally substituted.

Cycloalkyl—as used herein includes cyclic alkyl groups. The cycloalkyl groups may be those having 3 to 20 ring carbon atoms, preferably those having 4 to 10 carbon atoms. Examples of cycloalkyl include cyclobutyl, cyclopentyl, cyclohexyl, 4-methylcyclohexyl 4,4-dimethylcylcohexyl, 1-adamantyl, 2-adamantyl, 1-norbornyl, 2 -norbornyl, and the like. Of the above, preferred are cyclopentyl, cyclohexyl, 4-methylcyclohexyl, and 4,4-dimethyleylcohexyl. Additionally, the cycloalkyl group may be optionally substituted.

Heteroalkyl—as used herein, includes a group formed by replacing one or more carbons in an alkyl chain with a hetero-atom(s) selected from the group consisting of a nitrogen atom, an oxygen atom, a sulfur atom, a selenium atom, a phosphorus atom, a silicon atom, a germanium atom, and a boron atom. Heteroalkyl may be those having 1 to 20 carbon atoms, preferably those having 1 to 10 carbon atoms, and more preferably those having 1 to 6 carbon atoms. Examples of heteroalkyl include methoxymethyl, ethoxymethyl, ethoxyethyl, methylthiomethyl, ethylthiomethyl, ethylthioethyl, methoxymethoxymethyl, ethoxymethoxymethyl, ethoxyethoxyethyl, hydroxymethyl, hydroxyethyl, hydroxypropy, mercaptomethy, mercaptoethyl, mercaptopropyl, aminomethyl, aminoethyl, aminopropyl, dimethylaminomethyl, trimethylgermanylmethyl, trimethylgermanylethyl, trimethylgermanylisopropyl, dimethylethylgermanylmethyl, dimethylisopropylgermanylmethyl, tert-butylmethylgermanylmethyl, triethylgermanylmethyl, triethylgermanylethyl, triisopropylgermanylmethyl, triisopropylgermanylethyl, trimethylsilylmethyl, trimethylsilylethyl, and trimethylsilylisopropyl, triisopropylsilylmethyl, triisopropylsilylethyl. Additionally, the heteroalkyl group may be optionally substituted.

Alkenyl—as used herein includes straight chain, branched chain, and cyclic alkene groups. Alkenyl may be those having 2 to 20 carbon atoms, preferably those having 2 to 10 carbon atoms. Examples of alkenyl include vinyl, 1-propenyl group, 1-butenyl, 2-butenyl, 3-buteny, 1,3-butandienyl, 1-methylvinyl, styryl, 2,2-diphenylvinyl, 1,2-diphenylvinyl, 1-methylallyl, 1,1-dimethylallyl, 2-methylallyl, 1-phenytallyl, 2-phenylallyl, 3-phenylallyl, 3,3-diphenylallyl, 1,2-dimethylallyl, 1-phenyl-1-butenyl, 3-phenyl-1-butenyl, cyclopentenyl, cyclopentadienyl, cyclohexenyl, cyclohepteriyl, cycloheptatrienyl, cyclooctenyl, cyclooctatetraenyl, and norbornenyl. Additionally, the alkenyl group may be optionally substituted.

Alkynyl as used herein includes straight chain alkynyi groups. Alkynyl may be those having 2 to 20 carbon atoms, preferably those having 2 to 10 carbon atoms. Examples of alkynyl groups include ethynyl, propynyl, propargyl, 1-butynyl, 2-butynyl, 3-butynyl, 1-pentynyl, 2-pentynyl, 3,3-dimethyl-1-butynyl, 3-ethyl-3-methyl-1-pentynyl, 3,3-diisopropyl-1-pentynyl, phenylethynyl, phenylpropynyl, etc. Of the above, preferred are ethynyl, propynyl, propargyl, 1-butynyl, 2--butyryl, 3-butynyl, 1-pentynyl, and phenylethynyl. Additionally, the alkynyl group may be optionally substituted.

Aryl or an aromatic group—as used herein includes non-condensed and condensed systems. Aryl may be those having 6 to 30 carbon atoms, preferably those having 6 to 20 carbon atoms, and more preferably those having 6 to 12 carbon atoms. Examples of aryl groups include phenyl, biphenyl, terphenyl, triphenylene, tetraphenylene, naphthalene, anthracene, phenalene, phenanthrene, fluorene, pyrene, chrysene, perylene, and azulene, preferably phenyl, biphenyl, terphenyl, triphenylene, fluorene, and naphthalene. Examples of non-condensed aryl groups include phenyl, biphenyl-2-yl, biphenyl-3-yl, biphenyl-4-yl, p-terphenyl-4-yl, p-terphenyl-3-yl, p-terphenyl-2-yl, m-terphenyl-4-yl, m-telphenyl-3-yl, m-terphenyl-2-yl, o-tolyl, m-tolyl p-tolyl, p-(2-phenylpropyl)phenyl, 4′-methylbiphenylyl, 4″-t-butyl-p-terphenyl-4-yl, o-cumenyl, m-cumenyl, p-cumenyl, 2,5-xylyl, 3,4-xylyl, 2,5-xylyl, mesityl, and m-quarterphenyl. Additionally, the aryl group may be optionally substituted.

Heterocyclic groups—as used herein include non-aromatic cyclic groups. Non-aromatic heterocyclic groups include saturated heterocyclic groups having 3 to 20 ring atoms and unsaturated non-aromatic heterocyclic groups having 3 to 20 ring atoms, where at least one ring atom is selected from the group consisting of a nitrogen atom, an oxygen atom, a sulfur atom, a selenium atom, a silicon atom, a phosphorus atom, a germanium atom, and a boron atom. Preferred non-aromatic heterocyclic groups are those having 3 to 7 ring atoms, each of which includes at least one hetero-atom such as nitrogen, oxygen, silicon, or sulfur. Examples of non-aromatic heterocyclic groups include oxiranyl, oxetanyl, tetrahydrofuranyl, tetrahydropyranyl, dioxolanyl, dioxanyl, dihydropyrrolyl, tetrahydropyrrolyl, piperidinyl, oxazolidinyl, morpholinyl, piperazinyl, oxepinyl, thiepinyl, azepinyl, and tetrahydrosilolyl. Additionally, the heterocyclic group may be optionally substituted.

Heteroaryl13 as used herein, includes non-condensed and condensed hetero-aromatic groups having 1 to 5 hetero-atoms, where at least one hetero-atom is selected from the group consisting of a nitrogen atom, an oxygen atom, a sulfur atom, a selenium atom, a silicon atom, a phosphorus atom, a germanium atom, and a boron atom. A hetero-aromatic group is also referred to as heteroaryl. Heteroaryl may be those having 3 to 30 carbon atoms, preferably those having 3 to 20 carbon atoms, and more preferably those having 3 to 12 carbon atoms. Suitable heteroaryl groups include dibenzothiophene, dibenzofuran, dibenzoselenophene, furan, thiophene, benzofuran, benzothiophene, benzoselenophene, carbazole, indolocarbazole, pyridoindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxuzine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, benzofuropyridine, furodipyridine, benzothialopyridine, thienodipyridine, benzoselenophenopyridine, and selenophenodipyridine, preferably dibenzothiophene, dibenzofuran, dibenzoselenophene, carbazole, indolocarbazole, imidazole, pyridine, triazine, benzimidazole, 1,2-azaborine, 1,3-azaborine, 1,4-azaborine, borazine, and aza-analogs thereof. Additionally, the heteroaryl group may be optionally substituted.

Alkoxy—as used herein, is represented by —O-alkyl, —O-cycloalkyl, —O-heteroalkyl or —O-heterocyclic group. Examples and preferred examples of alkyl, cycloalkyl, heteroalkyl, and heterocyclic groups are the same as those described above. Alkoxy groups may be those having 1 to 20 carbon atoms, preferably those having 1 to 6 carbon atoms. Examples of alkoxy groups include methoxy, ethoxy, propoxy, butoxy, pentyloxy, hexyloxy, cyclopropyloxy, cyclobutyloxy, cyclopentyloxy, cyclohexyloxy, tetrahydrofuranyloxy, tetrahydropyranyloxy, methoxypropyloxy, ethoxyethyloxy, methoxymethyloxy, and ethoxymethyloxy. Additionally, the alkoxy group may be optionally substituted.

Aryloxy as used herein, is represented by —O-aryl or —O-hieteroaryl. Examples and preferred examples of aryl and heteroaryl are the same as those described above. Aryloxy groups may be those having 6 to 30 carbon atoms, preferably those having 6 to 20 carbon atoms. Examples of aryloxy groups include phenoxy and biphenyloxy. Additionally, the aryloxy group may be optionally substituted.

Arylalkyl—as used herein, contemplates alkyl substituted with an aryl group. Arylalkyl may be those having 7 to 30 carbon atoms, preferably those having 7 to 20 carbon atoms, and more preferably those having 7 to 13 carbon atoms. Examples of arylalkyl groups include benzyl, 1-phenylethyl, 2-phenylethyl, 1-phenylisopropyl, 2-phenylisopropyl, phenyl-t-butyl, alpha-naphthylmethyl, 1-alpha-naphthylethyl, 2-alpha-naphthylethyl, 1-alpha-naphthylisopropyl, 2-alpha-naphthylisopropyl, beta-naphthylmethyl, 1-beta-naphthylethyl, 2-beta-naphthylethyl, 1-beta-naphthylisopropyl, 2-beta-naphthylisopropyl, p-methylbenzyl, m-methylbenzyl, o-methylberizyl, p-chlorobenzyl, m-chlorobenzyl, o-chlorobenzyl, p-bromobenzyl m-bromobenzyl, o-brobenzyl, p-iodobenzyl, m-iodobenzyl, o-iodobenzyl, p-hydroxybenzyl, m-hydroxybenzyl, o-hydroxybenzyl, p-aminobenzyl, m-aminobenzyl, o-aminobenzyl, p-nitrobenzyl, m-nitrobenzyl, o-nitrobenzyl, p-cyanobenzyl, m-cyanobenzyl, o-cyanobenzyl, 1-hydroxy-2-phenylisopropyl, and 1-chloro-2-phenylisopropyl. Of the above, preferred are benzyl, p-cyanobenzyl, m-cyanobenzyl, o-cyanobenzyl, 1-phenylethyl, 2-phenylethyl, 1-phenylisopropyl, and 2-phenylisopropyl. Additionally, the arylalkyl group may be optionally substituted.

Alkylsilyi—as used herein, contemplates a silyl group substituted with an alkyl group. Alkylsilyl groups may be those having 3 to 20 carbon atoms, preferably those having 3 to 10 carbon atoms. Examples of alkylsilyl groups include trimethylsilyl, triethylsilyl, methyldiethylsilyl, ethyldimethylsilyl, tripropylsilyl, tributylsilyl, triisopropylsilyl, methyldiisopropylsilyl, dimethylisopropylsiyl, tri-t-butylsilyl, triisobutysilyl, dimethyl t-butylsilyl, and methyldi-t-butylsilyl. Additionally, the alkylsilyl group may be optionally substituted.

Arylsilyl—as used herein, contemplates a silyl tzroup substituted with an aryl group. Arylsilyl groups may be those having 6 to 30 carbon atoms, preferably those having 8 to 20 carbon atoms. Examples of arylsilyl groups include triphenylsilyl, phenyldibiphenylylsilyl, diphenylbiphenylsilyl, phenyldiethylsilyl, diphenylethylsilyl, phenyldimethylsilyl, diphenylmethylsilyl, phenyldiisopropylsilyl, diphenylisopropylsilyl, diphenylbutylsilyl, diphenylisobutylsilyl, diphenyl t-butylsilyl. Additionally, the arylsilyl group may be optionally substituted.

Alkylgermanyl—as used herein contemplates germanyl substituted with an alkyl group. The alkylgermanyl may be those having 3 to 20 carbon atoms, preferably those having 3 to 10 carbon atoms. Examples of alkylszermanyl include trimethylgermanyl, triethylgermanyl, methyldiethylgermanyl, ethyldimethylgermanyl, tripropylgermanyl, tributylgermanyl, trilsopropylgermanyl, methyldiisopropylgermanyl, dimethylisopropylgermanyl, tri-t-butylgermanyl, triisobutylgermanyl, dimethyl-t-butylgermanyl, and methyldi-t-butylgermanyl. Additionally, the alkylgermanyl may be optionally substituted.

Arylgermanyl—as used herein contemplates a germanyl substituted with at least one aryl group or heteroaryl group. Arylgermanyl may be those having 6 to 30 carbon atoms, preferably those having 8 to 20 carbon atoms. Examples of arylgermanyl include triphenylgermanyl, phenyldibiphenylylgermanyl, diphenylbiphenylgermanyl, phenyldiethylgermanyl, diphenylethylgermanyl, phenyldimethylgermanyl, diphenyimethylgermanyl, phenyldiisopropylgermanyl, diphenylisopropylgermanyl, diphenylbutylgermanyl, diphenylisobutylgermanyl, and diphenyl-t-butylgermanyl. Additionally, the arylgermanyl may be optionally substituted.

The term “aza” in azadibenzofuran, azadibenzothiophene, etc. means that one or more of C—H groups in the respective aromatic fragment are replaced by a nitrogen atom. For example, azatriphenylene encompasses dibenzo[f,h]quinoxaline, dibenzo[f,h]quinoline and other analogs with two or more nitrogens in the ring system. One of ordinary skill in the art can readily envision other nitrogen analogs of the aza-derivatives described above, and all such analogs are intended to be encompassed by the terms as set forth herein.

In the present disclosure, unless otherwise defined, when any term of the group consisting of substituted alkyl, substituted cycloalkyl, substituted heteroalkyl, substituted heterocyclic group, substituted arylaikyl, substituted alkoxy, substituted aryloxy, substituted alkenyl, substituted alkynyl, substituted aryl, substituted heteroaryl, substituted alkylsilyl, substituted arylsilyl, substituted alkylgernianyl, substituted arylgermanyl, substituted amino, substituted acyl, substituted carbonyl, a substituted carboxylic acid group, a substituted ester group, substituted sulfinyl, substituted sulfonyl, and substituted phosphino is used, it means that any group of alkyl, cycloalkyl, heteroalkyl, heterocyclic group, arylalkyl, alkoxy, aryloxy, alkenyl, alkynyl, aryl, heteroaryl, alkylsilyl, arylsilyl, amino, acyl, carbonyl, a carboxylic acid group, an ester group, sulfinyl, sulfonyl, and phosphino may be substituted with one or more moieties selected from the group consisting of deuterium, halogen unsubstituted alkyl having 1 to 20 carbon atoms, unsubstituted cycloalkyl having, 3 to 20 ring carbon atoms, unsubstituted heteroalkyl having 1 to 20 carbon atoms, an unsubstituted heterocyclic group having 3 to 20 ring atoms, unsubstituted arylalkyl having 7 to 30 carbon atoms, unsubstituted alkoxy having 1 to 20 carbon atoms, unsubstituted aryloxy having 6 to 30 carbon atoms, unsubstituted alkenyl having 2 to 20 carbon atoms, unsubstituted alkynyilhaviruz 2 to 20 carbon atoms, unsubstituted aryl having 6 to 30 carbon atoms, unsubstituted heteroaryl having 3 to 30 carbon atoms, unsubstituted alkylsilyl having 3 to 20 carbon atoms, unsubstituted arylsilyl haying 6 to 20 carbon atoms, unsubstituted alkylgermanyl having 3 to 20 carbon atoms, unsubstituted arylgermanyl group having 6 to 20 carbon atoms, unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof.

It is to be understood that when a molecular fragment is described as being a substituent or otherwise attached to another moiety, its name may be written as if it were a fragment (e.g. phenyl, phenylene, naphthyl, dibenzofuryl) or as if it were the whole molecule (e.g. benzene, naphthalene, dibenzofuran). As used herein, these different ways of designating a substituent or an attached fragment are considered to be equivalent.

In the compounds mentioned in the present disclosure, hydrogen atoms may be partially or fully replaced by deuterium. Other atoms such as carbon and nitrogen can also be replaced by their other stable isotopes. The replacement by other stable isotopes in the compounds may be preferred due to its enhancements of device efficiency and stability.

In the compounds mentioned in the present disclosure, multiple substitution refers to a range that includes a di-substitution, up to the maximum available substitution. When substitution in the compounds mentioned in the present disclosure represents multiple substitution (including di-, tri-, and tetra-substitutions, etc.), that means the substituent may exist at a plurality of available substitution positions on its linking structure, the substituents present at a plurality of available substitution positions may be the same structure or different structures.

In the compounds mentioned in the present disclosure, adjacent substituents in the compounds cannot be joined to form a ring unless otherwise explicitly defined, for example, adjacent substituents can be optionally joined to form a ring. In the compounds mentioned in the present disclosure, the expression that adjacent substituents can be optionally joined to form a ring includes a case where adjacent substituents may be joined to form a ring and a case where adjacent substituents are not joined to form a ring. When adjacent substituents can be optionally joined to form a ring, the ring formed may be monocyclic or polycyclic (including spirocyclic, endocyclic, fusedcyclic, and etc.), as well as alicyclic, heteroalicyclic, aromatic, or heteroaromatic. In such expression, adjacent substituents may refer to substituents bonded to the same atom, substituents bonded to carbon atoms which are directly bonded to each other, or substituents bonded to carbon atoms which are more distant from each other. Preferably, adjacent substituents refer to substituents bonded to the same carbon atom and substituents bonded to carbon atoms which are directly bonded to each other.

The expression that adjacent substituents can be optionally joined to form a ring is also intended to mean that two substituents bonded to the same carbon atom are joined to each other via a chemical bond to form a ring, which can be exemplified by the following formula:

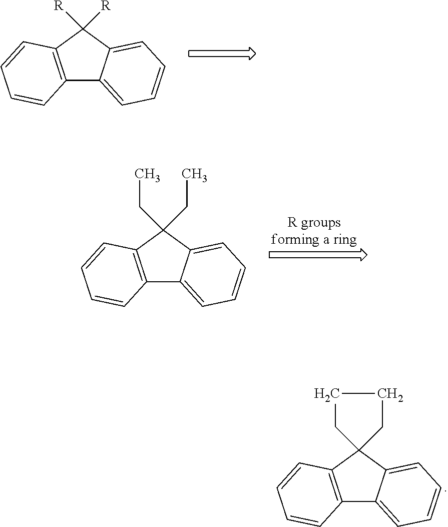

The expression that adjacent substituents can be optionally joined to form a ring is also intended to mean that two substituents bonded to carbon atoms which are directly bonded to each other are joined to each other via a chemical bond to form a ring, which can be exemplified by the following formula:

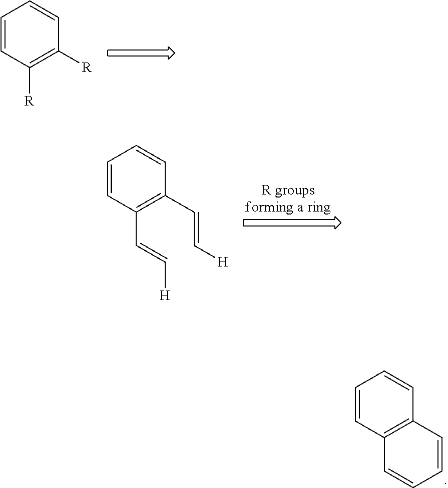

The expression that adjacent substituents can be optionally joined to form a ring is also intended to mean that two substituents bonded to a further distant carbon atom are joined to each other via a chemical bond to form a ring, which can be exemplified by the following formula:

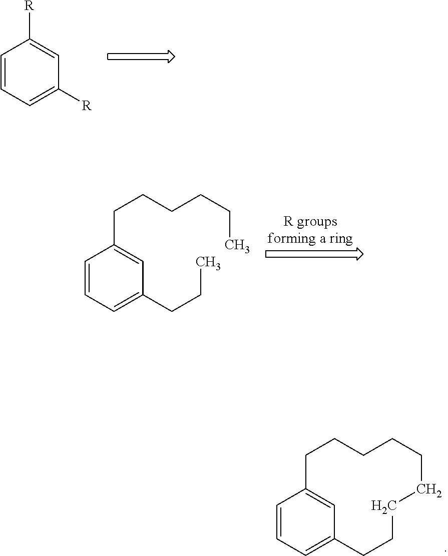

Furthermore, the expression that adjacent substituents can be optionally joined to form a ring is also intended to mean that, in the case where one of the two substituents bonded to carbon atoms which are directly bonded to each other represents hydrogen, the second substituent is bonded at a position at which the hydrogen atom is bonded, thereby forming a ring. This is exemplified by the following formula:

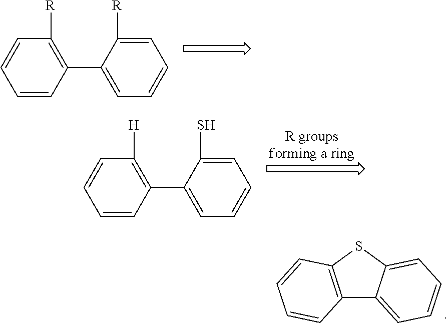

According to an embodiment of the present disclosure, an organic electroluminescent device is disclosed;
the organic electroluminescent device includes a cathode, an anode, and an organic layer disposed between the cathode and the anode;
wherein the organic layer includes a metal complex, and the metal complex includes a metal M and at least one C\hat{ }N bidentate ligand Lₐ coordinated to the metal M;
the metal M is selected from a metal with a relative atomic mass greater than 40;
when two or more ligands Lₐ are present at the same time, the two or more ligands Lₐ may be identical or different;
at least one ligand Lₐ includes at least one substituent A;
the substituent A is, at each occurrence identically Or differently, selected from a substituted or unsubstituted non-aromatic group having 1 to 20 carbon atoms;
when two or more substituents A are present at the same time, the two or more substituents A may be identical or different; and
the capacitance characteristics of the metal conwlex in an electroluminescent device satisfy:
at 500 Hz, a maximum capacitance of the electroluminescent device is Cₘₐₓ; and
at 500 Hz, a change in the maximum capacitance caused by the substituent A is ΔCₘₐₓ≤−0.12 n.F.

As used herein, “electroluminescent device” in the “capacitance characteristics of the metal complex in an electroluminescent device” refers to any organic electroluminescent device, including, but not limited to, the following device adopted in the embodiment of the present application: ITO with a thickness of 80 nm is deposited as an anode; Compound H1 is deposited as an HIL with a thickness of 100 Å; Compound HT is deposited as and HTL with a thickness of 350 Å; Compound H1 is deposited as an EBL with a thickness of 50 Å; the metal complex, Compound H1 and Compound H2 (at a weight ratio of 6:47:47) are co-deposited as an emissive layer (EML) with a thickness of 400 Å; Compound HB is deposited as an HBL with a thickness of 50 Å; Compound ET and Liq (at a weight ratio of 40:60) are co-deposited as an ETL with a thickness of 350 Å; Liq with a thickness of 1 nm is deposited as an EIL; aluminum with a thickness of 120 nm is deposited as a cathode. The specific structures of the above compounds are shown in the device examples described below. The specific device in the preceding embodintent of the present disclosure is exemplary only, and those skilled in the art can adjust the structure of the device as required in a manner that includes, but is not limited to, 1) adjusting the thickness of any one of the layers, for example, increasing or decreasing 20 Å on the basis of the thickness of the organic layers in the preceding; device; 2) selecting suitable material combinations for any one of the layers, for example, selecting different types of host materials or different weight ratios for the host materials in the preceding emissive layers as required; and 3) even adding or reducing some functional layers, for example, omitting; the EBL and/or the HBL in the preceding device or using a plurality of HILs. The present application does not limit which devices the metal complex is applied to, and the present application only exemplifies the application of the metal complex in particular devices in the embodiments. Those skilled in the art can adjust the device shown herein or can apply the metal complex to other devices such as laminated devices, based on knowledge of the devices.

Herein, “a change in the maximum capacitance caused by the substituent A is ΔCₘₐₓ≤−0.12 nF” is intended to means: a metal complex X_{A} including a ligand Lₐ having at least one substituent A is applied to any electroluminescent device Y_{A} having a geometric capacitance of C_{geo}, when a voltage V₀ equal to the voltage V_{Cmax} is applied to the electroluminescent device Y_{A}, the maximum capacitance of the device is measured as Cₘₐₓ; another metal complex X including a ligand L (the metal complex X differs from the metal complex X_{A} only in that the ligand L differs from the ligand Lₐ, and the ligand L differs from the ligand Lₐ only in whether there is a substituent A; while, the metal complex X_{A} may also optionally differ from the metal complex X in hydrogen and deuterium) is applied to an electroluminescent device Y (the electroluminescent device Y differs from the electroluminescent device Y_{A} only in that the metal complex X_{A} in the device Y_{A} is replaced with the metal complex X) having a geometric capacitance of C_{geo0}, when a voltage V₀ equal to the voltage V_{Cmax0} is applied to the electroluminescent device Y, the maximum capacitance of the device is measured as Cₘₐₓ₀; in this case, the change in the maximum capacitance caused by the substituent A is ΔCₘₐₓ=Cₘₐₓ−Cₘₐₓ₀≤−0.12 nF. It is to be noted that the change in the maximum capacitance. ΔCₘₐₓ defined herein is the decrease in capacitance caused by substituent A, that is, indicating Cₘₐₓ<Cₘₐₓ₀. In the present application, since the electroluminescent devices Y_{A} and Y differ only in that the emissive materials in the emissive layers are different, C_{geo} and C_{geo0} are substantially identical, and the difference thereof is only in the range of ±0.05 nF. Cₘₐₓ−Cₘₐₓ₀ represents the capacitance change value of the device Y_{A} when the applied voltage V₀ increases from Vₜ to V_{Cmax}, and Cₘₐₓ₀−C_{geo0} represents the capacitance change value of the device Y when the applied voltage V₀ increases from Vₜ to V_{Cmax}. It is to be noted that the maximum capacitance Cₘₐₓ of the organic electroluminescent device Y_{A}, the maximum capacitance Cₘₐₓ₀ of the organic electroluminescent device Y and ΔCₘₐₓ=Cₘₐₓ−Cₘₐₓ₀≤−0.12 nF are all values measured under the following condition: the emissive areas of the organic electroluminescent device Y_{A} and the organic electroluminescent device Y are both 0.04 cm². It is to be understood by those skilled in the art that if the emissive area of the device changes, the corresponding maximum capacitance Cₘₐₓ₀ and Cₘₐₓ and ΔCₘₐₓ, naturally change in accordance with the law of “the maximum capacitance per unit of emissive area of the device=capacitance maxima/emissive area”.

Herein, “C\hat{ }N bidentate ligand” refers to a ligand in which the ligand is directly or indirectly bonded to a center atom (a metal or a metalloid) via two coordination atoms (that is, carbon and nitrogen). Direct bonding means that the coordination atom “carbon” is directly bonded to the metal to form a metal-carbon bond and the coordination atom “nitrogen” is directly bonded to the metal to fomi a metal-nitrogen bond. Indirect bonding means that the coordination atom “carbon” is bonded to the metal via an atom G to form a metal-G-carbon bond and the coordination atom “nitrogen” is bonded to the metal via the atom G to the metal to form a metal-G-nitrogen bond.

According to an embodiment of the present disclosure, at 500 Hz, the change in t maximum capacitance caused by the substituent A is ΔCₘₐₓ≤−0.17 nF.

According to au embodiment of the present disclosure, at 500 Hz, the change in the maximum capacitance caused by the substituent A is ΔCₘₐₓ≤−0.19 nF.

According to an embodiment of the present disclosure, at 500 Hz, the change in the maximum capacitance caused by the substituent A is ΔCₘₐₓ≤−0.24 nF.

According to an embodiment of the present disclosure, at 500 Hz, 1.0 nF≤Cₘₐₓ₀≤6.00 nF, and in the electroluminescent device, 0.5 nF≤Cₘₐₓ≤5.0 nF.

According to an embodiment of the present disclosure, at 500 Hz, 1.5 nF≤Cₘₐₓ₀≤6.00 nF, and in the electroluminescent device, 0.5 nF≤Cₘₐₓ≤5.0 nF.

According to an embodiment of the present disclosure, at 500 Hz, 2.0 nF≤Cₘₐₓ₀≤6.00 nF, and in the electroluminescent device, 0.5 nF≤Cₘₐₓ≤4.0 nF.

According to an embodiment of the present disclosure, at 500 Hz, 2.5 nF≤Cₘₐₓ₀≤6.00 nF, and in the electroluminescent device, 0.5 nF≤Cₘₐₓ≤3.5 nF.

According to an embodiment of the present disclosure, at 500 Hz, 0.42 nF≤Cₘₐₓ₀−C_{geo0}≤3.80 nF, and in the electroluminescent device, 0.30 nF≤Cₘₐₓ−C_{geo}≤3.68 nF.

According to an embodiment of the present disclosure, at 500 Hz, 1.30 nF≤Cₘₐₓ₀−C_{geo0}≤3.80 nF and in the electroluminescent device, 0.30 nF≤Cₘₐₓ−C_{geo}≤2.80 nF.

According to an embodiment of the present disclosure, at 500 Hz, 1.80 nF≤Cₘₐₓ₀−C_{geo0}≤3.80 nF, and in the electroluminescent device, 0.30 nF≤Cₘₐₓ−C_{geo}≤2.30 nF.

According to an embodiment of the present disclosure, at 500 Hz, an initial voltage: Vₜ of the electroluminescent device satisfies: −4.0 V≤Vₜ≤5.0 V.

According to an embodiment of the present disclosure, at 500 Hz, the initial voltage Vₜ of the electroluminescent device satisfies: −2 V≤Vₜ≤4.0 V.

According to an embodiment of the present disclosure, at 500 Hz, the initial voltage Vₜ of the electrolurrl.inescent device satisfies: −1.0 Vₜ≤3.0 V.

According to an embodiment of the present disclosure, at 500 Hz, when the capacitance of the electroluminescent device reaches the maximum value Cₘₐₓ, a corresponding voltage V_{Cmax} satisfies: 1.0 V≤V_{Cmax}≤6.0 V.

According to an embodiment of the present disclosure, at 500 Hz, when the capacitance of the electroluminescent device reaches the maximum value Cₘₐₓ, the corresponding voltage V_{Cmax}, satisfies: 1.5 V≤V_{Cmax}≤5.0 V.

According to an embodiment of the present disclosure, at 500 Hz, when the capacitance of the electroluminescent device reaches the maximum value Cₘₐₓ, the corresponding voltage V_{Cmax} satisfies: 2.0 ≤V_{Cmax}≤4.0 V.

According to an embodiment of the present disclosure, a highest occupied molecular orbital energy level (E_{HOMO}) of the metal complex is less than or equal to −5.05 eV.

According to an embodiment of the present disclosure, the highest occupied molecular orbital energy level of the metal complex is less than or equal to −5.10 eV.

According to an embodiment of the present disclosure, the highest occupied molecular orbital energy level of the metal complex is less than or equal to −5.15 eV.

According to an embodiment of the present disclosure, a lowest unoccupied molecular orbital energy level (E_{LUMO}) of the metal complex is less than or equal to −2.10 eV.

According to an embodiment of the present disclosure, the lowest unoccupied molecular orbital energy level of the metal complex is less than or equal to −2.15 eV.

According to an embodiment of the present disclosure, the lowest unoccupied molecular orbital energy level of the metal complex is less than or equal to −2.20 eV.

According to an embodiment of the present disclosure, the substituent A is, at each occurrence identically or differently, selected from substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, or substituted or unsubstituted heterocyclic group having 3 to 20 ring atoms.

According to an embodiment of the present disclosure, the substituent A is, at each occurrence identically or differently, selected from substituted or unsubstituted alkyl having 1 to 12 carbon atoms, or substituted or unsubstituted cycloalkyl having 3 to 12 ring carbon atoms.

According to an embodiment of the present disclosure, the substituent A is, at each occurrence identically or differently, selected from substituted or unsubstituted alkyl having 3 to 6 carbon atoms, or substituted or unsubstituted cycloalkyl having 3 to 6 ring carbon atoms.

According to an embodiment of the present disclosure, the organic layer including the metal complex is an emissive layer.

According to an embodinumt of the present disclosure, the emissive layer further includes a first host compound.

According to an embodiment of the present disclosure, the emissive layer further includes a first host compound and a second host compound.

According to an embodiment of the present disclosure, the first host compound and/or the second host compound include at least one chemical group selected from the group consisting of: benzene, pyridine, pyrimidine, triazine, carbazole, azacarbazole, indolocarbazole, dibenzothiophene, azadibenzothiophene, dibenzofuran, azadibenzofuran, dibenzoseophene, triphenylene, azatriphenylene, fluorene, silafluorene, naphthalene, quinoline, isoquinoline quinazoline, quinoxaline, phenanthrene, azaphenanthrene, and combinations thereof.

According to an embodiment of the present disclosure, the first host compound and the second host compound may be the following: the first host compound and the second host compound are both p-type host materials; the first host compound and the second host compound are both n-type host materials; the first host compound is a p-type host material, and the second host compound is an n-type host material.

According to an embodiment of the present disclosure, the metal complex is doped in the first host compound and the second host compound, and a weight of the metal complex accounts for 1% to 30% of a total weight of the organic layer.

According to an embodiment of the present disclosure, the metal complex is doped in the first host compound and the second host compound, and the weight of the metal complex accounts for 3% to 13% of the total weight of the organic layer.

According to an embodiment of the present disclosure, the organic electroluminescent device is a top-emitting device.

According to an embodiment of the present disclosure, the organic electroluminescent device is a bottom-emitting device.

According to an embodiment of the present disclosure, the organic electroluminescent device is a laminated device.

According to an embodiment of the present disclosure, the organic electroluminescent device is a single-layer device.

According to an embodiment of the present disclosure, the metal complex in the organic electroluminescent device has a general formula of M(Lₐ)ₘ(L_{b})ₙ(L_{c})_{q};
Lₐ, and L_{b}, and L_{c} are a first ligand, a second ligand and a third ligand coordinated to the metal M, respectively, and Lₐ, and L_{b}, and L_{c} are identical or different; wherein Lₐ, and L_{b}, and L_{c} can be optionally joined to form a tetradentatc ligand or a multidentate ligand;
m is selected from 1, 2 or 3, n is selected from 0, 1 or 2, q is selected from 0, 1 or 2, and m+n+q equals an oxidation state of the metal M; when m is greater than or equal to 2, a plurality of Lₐ are identical or different, when n is equal to 2, two L_{b} are identical or different, when q is equal to 2, two L_{c} are identical Or different;
Lₐ is, at each occurrence identically or differently, selected from a C\hat{ }N bidentate ligand; the metal M is selected from a metal with a relative atomic mass greater than 40;
Lₐ has a structure of E-F,
wherein E is, at each occurrence identically or differently, selected from a substituted or unsubstituted heteroaromatic ring having 5 to 30 ring atoms, the heteroaromatic ring includes at least one nitrogen atom, and F is bonded to the metal through the nitrogen atom in the heteroaromatic ring to form a metal-nitrogen bond or a metal-G-nitrogen bond;
F is, at each occurrence identically or differently, selected from a substituted or unsubstituted aromatic ring having 6 to 30 ring atoms, a substituted or unsubstituted heteroaromatic ring having 5 to 30 ring atoms or combinations thereof, and the ring F is bonded to the metal through the carbon atom in the aromatic ring or the heteroaromatic ring to form a metal-carbon bond or a metal-G-carbon bond;
F has at least one substituent A, and/or when F is a multi-membered fused ring, E has at least one substituent A;
when two or more substituents A are present at the same time, the two or more substituents A are identical or different;
the substituent A is, at each occurrence identically or differently, selected from a substituted or unsubstituted non-aromatic group having 1 to 20 carbon atoms;
G is, at each occurrence identically or differently, selected from O or S;
the substituent A can be optionally joined to other substituents in the ligand Lₐ to form a ring; and
adjacent substituents can be optionally joined to form a ring; and
L_{b} and L_{c} are, at each occurrence identically or differently, selected from a monoanionic bidentate ligand.

According to an embodiment of the present disclosure, in addition to the substituent A, the metal complex at least further includes one substituent selected from the group consisting of deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sullinyl group, a sulfonyl group, a phosphino group, and combinations thereof.

According to an embodiment of the present disclosure, in addition to the substituent A, the metal complex at least further includes one substituent selected from the group consisting of: halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted alkylgermanyl having 3 to 20 carbon atoms, a cyano group, an isocyano group, and combinations thereof.

According to an embodiment of the present disclosure, in addition to the substituent A, the metal complex at least further includes one substituent selected from the group consisting of: fluorine, substituted or unsubstituted alkyl having 1 to 6 carbon atoms, substituted or unsubstituted cycloalkyl having 3 to 6 ring carbon atoms, substituted or unsubstituted aryl having 6 to 12 carbon atoms, substituted or unsubstituted heteroaryl having 3 to 30 carbon atoms, substituted or unsubstituted alkylsilyl having 3 to 12 carbon atoms, substituted or unsubstituted alkylgermanyl having 3 to 12 carbon atoms, a cyano group, and combinations thereof.

According to an embodiment of the present disclosure, in addition to the substituent A, the ligand Lₐ at least further includes one substituent selected from fluorine or a cyano group.

According to an embodiment of the present disclosure, in addition to the substituent A, the metal complex at least further includes two substituents, wherein one of the two substituents is selected from fluorine or a cyano group, and the other is selected from the group consisting of: deuterium, halogen, substituted or unsubstituted alkyl having 1 to 20 carbon atoms, substituted or unsubstituted cycloalkyl haying 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl haying 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sultanyl group, a sulfinyl group, a sulfonyl group, a phosphino group, and combinations thereof.

According to an embodiment of the present disclosure, in addition to the substituent A, the metal complex at least further includes two substituents, wherein one of the two substituents is selected from fluorine or a cyano group, and the other is selected from the group consisting substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted alkylgermanyl having 3 to 20 carbon atoms, and combinations thereof.

According to an embodiment of the present disclosure, the metal M is, at each occurrence identically or differently, selected from the group consisting of Cu, tg, Au, Ru, Rh, Pd, Os, Ir, and Pt.

According to an embodiment of the present disclosure, the metal M is, at each occurrence identically or differently, selected from Pt or Ir.

According to an embodiment of the present disclosure, a maximum external quantum efficiency (EQE) of the organic electrolumlinescent device at 15 mA/cm² is greater than or equal to 21%.

According to an embodiment of the present disclosure, the maximum external quantum efficiency (EQE) of the organic electroluminescent device at 15 mA/cm² is greater than or equal to 22%.

According to an embodiment of the present disclosure, the maximum external quantum efficiency (EQE) of the organic electroluminescent device at 15 mA/cm² is greater than or equal to 23%.

According to another object of the present disclosure, a display assembly is disclosed. The display assembly includes the organic electroluminescent device described in any one of the preceding embodiments.

According to another object of the present disclosure, a metal complex is further independently disclosed;
the metal complex has a general formula of M(Lₐ)ₘ(L_{b})ₙ(L_{c})_{q}, wherein Lₐ, and L_{b}, and L_{c} are a first ligand, a second ligand and a third ligand coordinated to a metal M, respectively, and Lₐ, and L_{b}, and L_{c} are identical or different; wherein Lₐ, and L_{b}, and L_{c} can be optionally joined to form a tetradentate ligand or a multidentate ligand;
m is selected from 1, 2 or 3., n is selected from 0, 1 or 2, q is selected from 0, 1 or 2, and m+n+q equals an oxidation state of the metal M; when M is greater than or equal to 2, a plurality of Lₐ are identical or different; when n is equal to 2, two are identical or different; when q is equal to 2, two are identical or different;
Lₐ is, at each occurrence identically or differently, selected from a bidentate ligand;
the metal M is selected from a metal with a relative atomic mass greater than 40;
Lₐ has a structure of E-F,
wherein E is, at each occurrence identically or differently, selected from a substituted or unsubstituted heteroaromatic ring having 5 to 30 ring atoms, the heteroaromatic ring includes at least one nitrogen atom, and E is bonded to the metal through the nitrogen atom in the heteroaromatic ring to form a metal-nitrogen bond or a metal-G-nitrogen bond;
F is, at each occurrence identically or differently, selected from a substituted or unsubstituted aromatic ring having 6 to 30 ring atoms, a substituted or unsubstituted heteroaromatic ring having 5 to 30 ring atoms or combinations thereof, and the ring F is bonded to the metal through the carbon atom in the aromatic ring or the heteroaromatic ring to form a metal-carbon bond or a metal-G-carbon bond;
F has at least one substituent A, and/or when F is a multi-membered fused ring, F has at least one substituent A;
when two or more substituents A are present at the same time, the two or more substituents A are identical or different,
the substituent A is, at each occurrence identically or differently, selected from a substituted or unsubstituted non-aromatic group having 1 to 20 carbon atoms;
G is, at each occurrence identically or difierently, selected from O or S;
adjacent substituents can be optionally joined to form a ring; and
the substituent A can be optionally joined to other substituents in the ligand Lₐ to form a ring;

L_{b} and L_{c} are, at each occurrence identically or differently, selected from ar monoanionic bidentate ligand; and
the metal complex in an electroluminescent device satisfies:
at 500 Hz, a maximum capacitance of the electroluminescent device is Cₘₐₓ; and
at 500 Hz, a change in the maximum capacitance caused by the substituent A is ΔCₘₐₓ≤−0.12 nF.

According to an embodiment of the present osure, the ligand Lₐ has a structure represented by Formula 1:

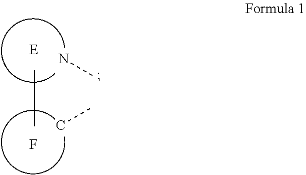

wherein
the ring E is, at each occurrence identically or differently, selected from a heteroaromatic ring having 5 to 30 ring atoms which is unsubstituted or is substituted with one or more Rₑ, the heteroaromatic ring includes at least one nitrogen atom, and E is bonded to the metal through the nitrogen atom in the heteroaromatic ring to form a metal-nitrogen bond;
the ring F is, at each occurrence identically or differently, selected from an aromatic ring having 6 to 30 ring atoms which is unsubstituted or is substituted with one or more R_{f}, a heteroaromatic ring having 5 to 24 ring atoms which is unsubstituted or is substituted with one or more R_{f}, or combinations thereof, and the ring is bonded to the metal through the carbon atom in the aromatic ring or the heteroaromatic ring to form a metal-carbon bond;
Rₑ, and R_{f} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstitutedheteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted aryltzermanyl havinfz. 6 10 to 20 carbon atoms, substituted or unsubstituted amino having 0 to 20 carbon atoms, an acyl group, a carbonyl group, a carboxylic acid group, an ester group, a cyano group, an isocyano map, a hydroxyl group, a sullitnyl map, a sulfinyl group, a sulfonyl wroup, a phosphino group, and combinations thereof; and
adjacent substituents Rₑ and R_{f} can be optionally joined to form a ring.

Herein, the expression that “adjacent substituents Rₑ and R_{f} can be optionally joined to form a ring” is intended to mean that any one or more of groups of adjacent substituents, such as two substituents Rₑ, two substituents R_{f}, and substituents Rₑ and R_{f}, can be optionally joined to form a ring. Apparently, it is also possible that none of these groups are joined to fonn a ring.

According, to an embodiment of the present disclosure, the substituent A is on the ring F in Formula 1.

According to an embodiment of the present disclosure, the substituent A is on the ring F in Formula 1, and when the ring F is a multi-membered fused ring, the substituent A is on a ring in the ring F which is directly bonded to the metal.

According to an embodiment of the present disclosure, when the ring F is a multi-membered fused ring, the substituent A is on the ring E in Formula 1.

According to an embodiment of the present disclosure, in the metal complex, the substituent A is, at each occurrence identically or differently, selected from the group consisting of A-1 to A-86:

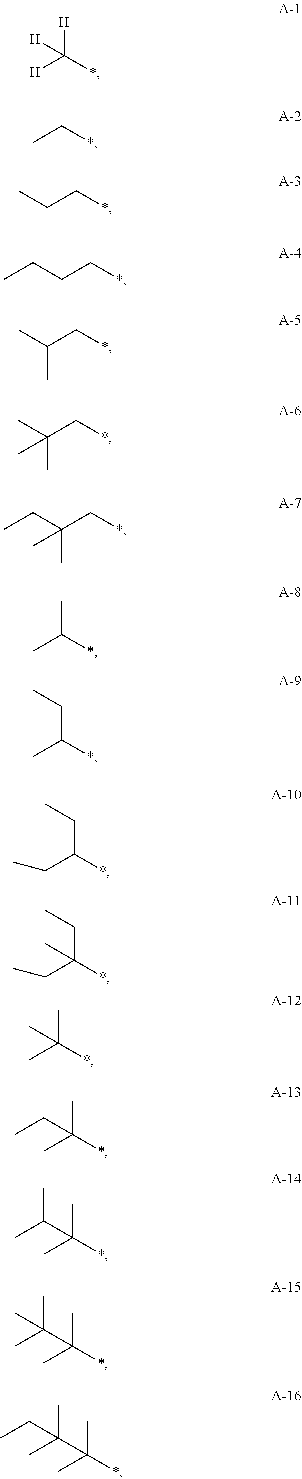

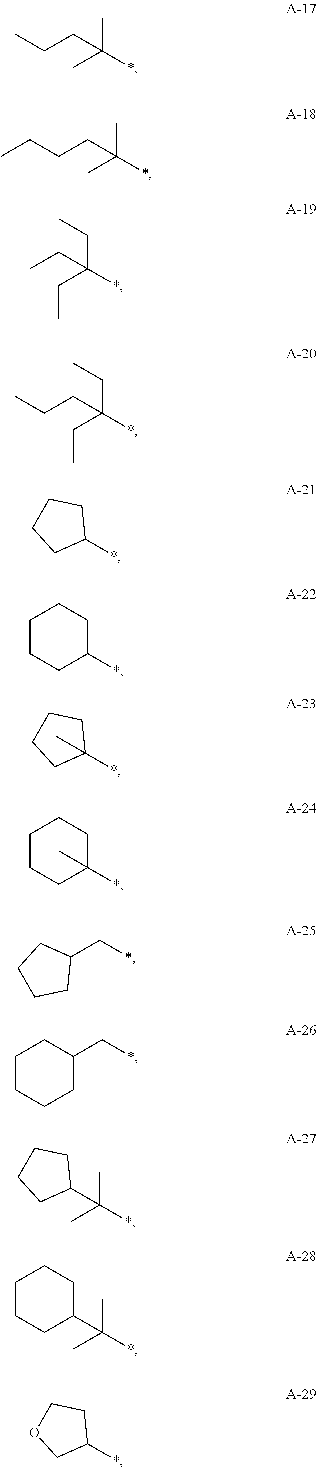

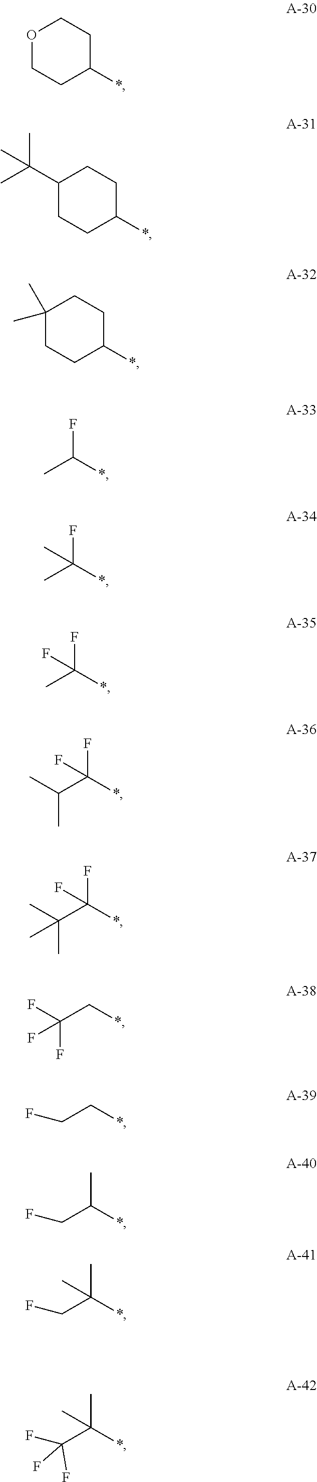

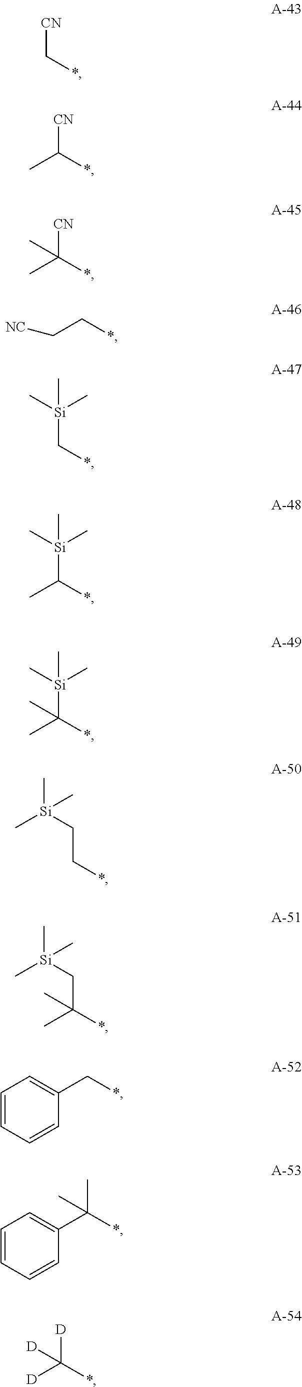

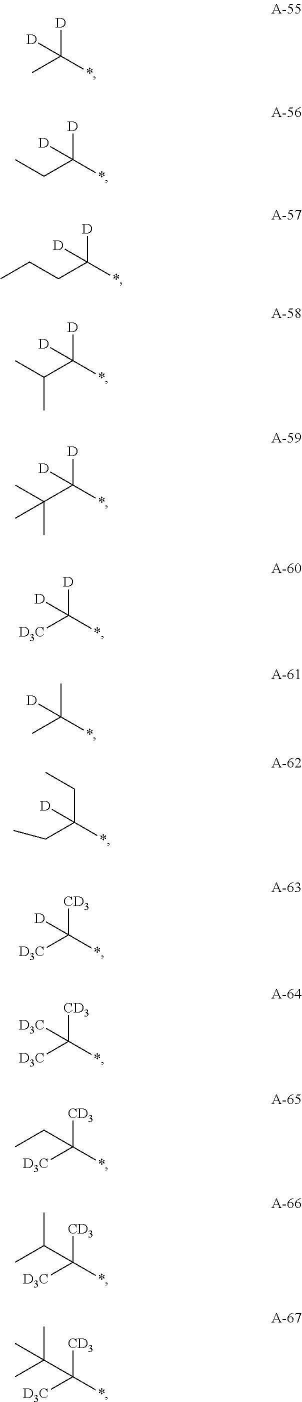

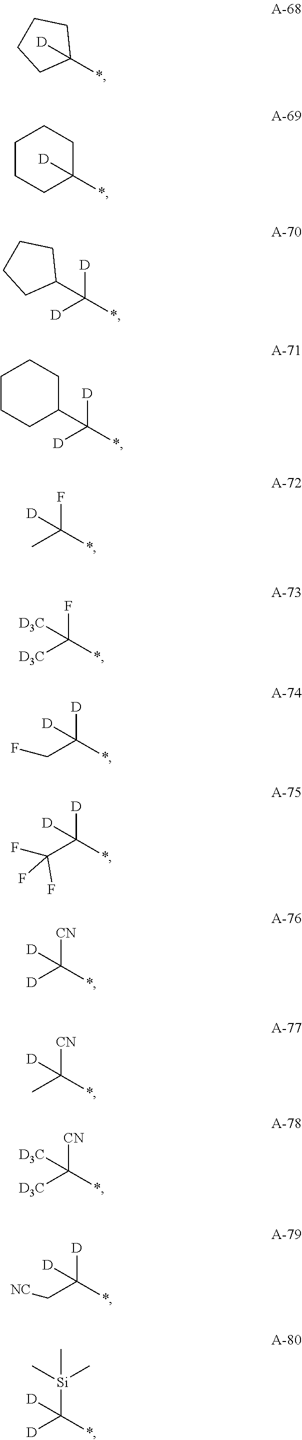

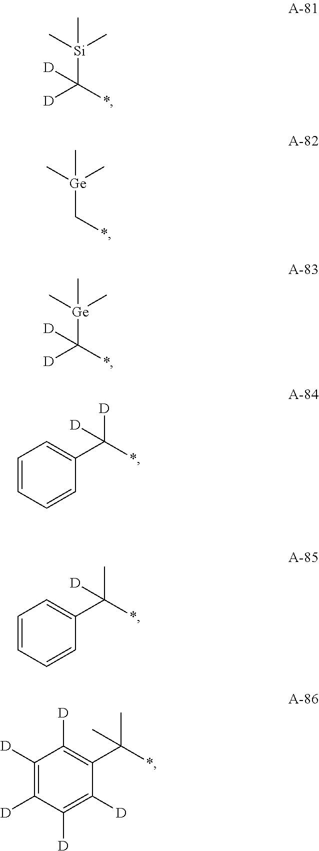

and combinations hereof; and
optionally, hydrogens in the above groups can be partially or fully substituted with deuterium; wherein “*” represents a position of attachment of the substituent A to the ring E and/or the ring F.

According to an embodiment of the present disclosure, the ring E has structures represented by Formula E-1 or Formula E-7:

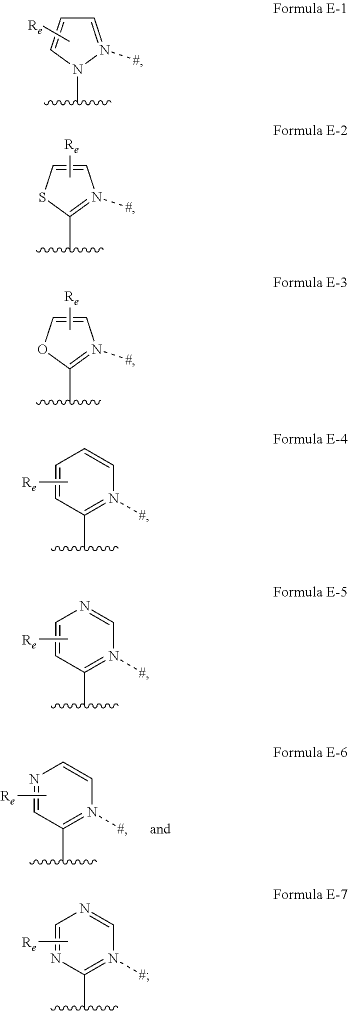

wherein
Rₑ is, at each occurrence identically or differently, selected from the group consisting of hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atonis, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R can be optionally joined to form a ring; and
in Formula E-1 or Formula E-7, “#” represents a position of attachmentthe ring E to the metal M, and

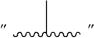

represents a position of attachment of the ring E to the ring F in Formula 1.

Herein, the expression that “adjacent substituents Rₑ can be optionally joined to form a ring” is intended to mean that any one or more of groups consisting of any two adjacent substituents Rₑ can be optionally joined to form a ring. Apparently, it is also possible that none of these groups are joined to form a ring.

According to an embodiment of the present disclosure, the ring E has the structure represented by Formula E-4.

According to an embodiment of - present disclosure, the ring F has structures represented by Formula F-1 or Formula F-5:

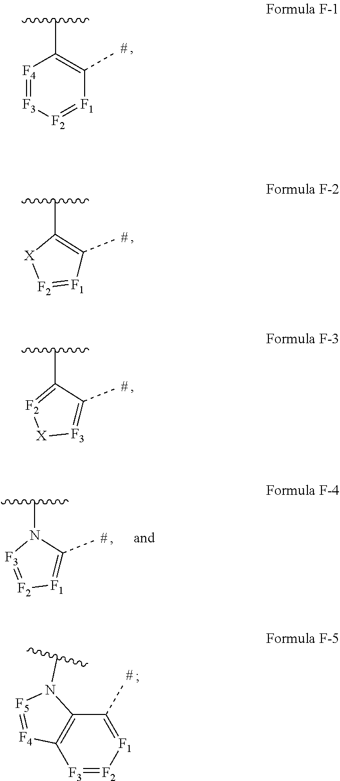

wherein. X is selected from O, S, Se, CRR, SiRR or NR;
F₁ to F₅ are, at each occurrence identically or differently, selected from CR_{f} or N, and when two R_{f} are present at the same time, the two R_{f} are identical or different;
R and R_{f} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkenyl having 2 to 20 carbon atoms, substituted or unsubstituted aryl having 6 to 30 carbon atonis, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfontl group, a phosphino group, and combinations thereof;
adjacent substituents R and R_{f} can be optionally joined to form a ring; and
in Formula F-1 or Formula F-5, “#” represents a position of attachment of the ring to the metal M, and

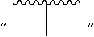

represents a position of atta hment of the ring F to the ring E in Formula 1.

Herein, the expression that “adjacent substituents R and R_{f} can be optionally joined to form a ring” is intended to mean that any one or more of groups of adjacent substituents, such as two substituents R, two substituents R_{f}, and substituents R and R_{f}, can be optionally joined to form a ring. Apparently, it is also possible that none of these groups are joined to form a ring.

According to an embodiment of the present disclosure, the ring F has the structure represented by Formula F-1.

According to an embodiment of the present disclosure, the ring F is, at each occurrence identically or differently, selected from any one of the following structures:

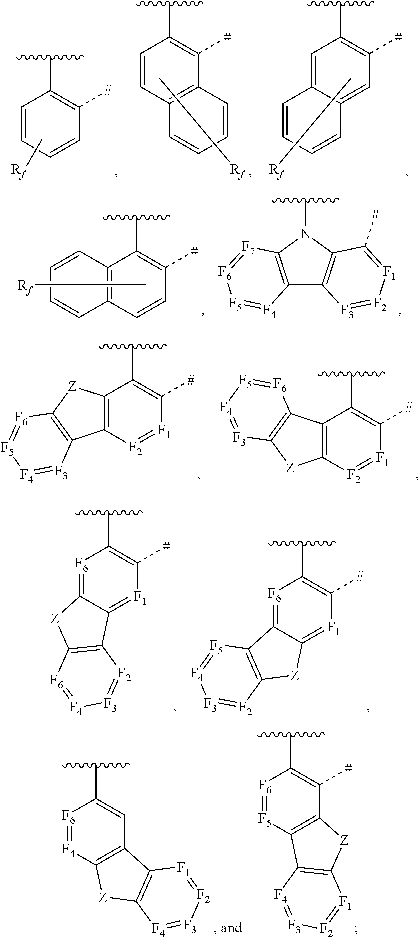

wherein
Z is selected from the group consisting of O, S, Sc, NR′, CR′R′, SiR′R′, and GeR′R′, and when two R′ are present at the same time, the two R′ are identical or different;
F₁ to F₇ are, at each occurrence identically or differently, selected from CR_{f} or N;
R_{f} represents, at each occurrence identically or differently, mono-substitution, multiple substitutions or non-substitution;
R_{f} and R′ are, at each occurr ence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl haying 2 to 20 carbon atoms, substituted or unsubstituted aryl having 6 to 30 carbon atoms, substituted or unsubstituted heteroaryl having 3 to 30 carbon atoms, substituted or unsubstituted allylsilyl having 3 to 20 catbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted ammo having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R_{f} and R′ can be optionally joined to form a ring; and
“#” represents a position of attachment ofthe ring F to the metal M, and

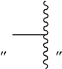

represents a position of attachment of the ring F to the ring E in Formula 1.

Herein, the expression that “adjacent substituents R_{f} and R′ can be optionally joined to form a ring” is intended to mean that any one or more of groups of adjacent substituents, such as two substituents R′, two substituents R_{f}, and substituents R′ and R_{f}, can be optionally joined to form a ring. Apparently, it is also possible that none of these groups are joined to form a ring.

According to an embodiment of the present disclosure, the ligand Lₐ is, at each occurrence identically or differently, selected from structures represented by Formula 1-1 and/or Formula 1-2:

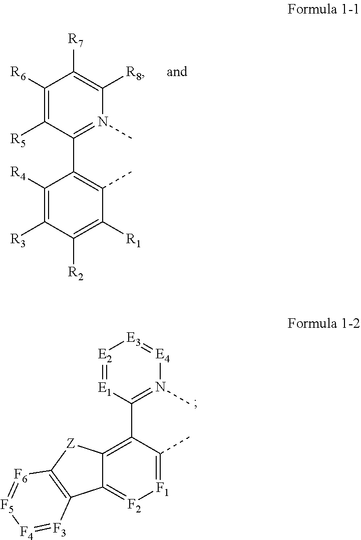

wherein Z is selected from the group consisting of O, S, Se, NR′, CR′R′, SiR′R′, and GeR′R′, and when two R′ are present at the same time, the two R′ are identical or different;
E₁ to E₄ are, at each occurrence identically or differently, selected from CRₑ or N;
F₁ to F₆ are, at each occurrence identically or differently, selected from CR_{f} or N;
when the ligand Lₐ has the structure represented by Formula 1-1, at least one of R₁ to R₄ is the substituent A;
when the ligand Lₐ has the structure represented by Formula 1-2, at least one of E₁ to E₄ is CRₑ, and Rₑ is the substituent A; andior at least one of F₁ and F₂ is CR_{f}, and R_{f} is the substituent A;
R₁ to R₈, R′, Rₑ, and R_{f} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsityl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
the substituent A is, at each occurrence identically or differently, selected from substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms or substituted or unsubstituted heterocyclic group having 3 to 20 ring atoms;
adjacent substituents in R₁ to R₈ can be optionally joined to form a ring; and
adjacent substituents in R′, Rₑ, and R_{f} can be optionally joined to form a ring.

Herein, the expression that “adjacent substituents in R′, Rₑ, and R_{f} can be optionally joined to form a ring” is intended to mean that any one or more of groups of adjacent substituents, such as two substituents R′, two substituents R_{f}, two substituents Rₑ and substituents R′ and R_{f}, can be optionally joined to form a ring. Apparently, it is also possible that none of these groups are joined to form a ring.

Herein, the expression that “adjacent substituents in R₁ to R₈ can be optionally joined to form a ring” is intended to mean that any one or more of groups consisting of any two adjacent substituents in R₁ to R₈ can be optionally joined to form a ring. Apparently, it is also possible that none of these groups are joined to form a ring.

According to an embodiment of the present disclosure, the substituent A is, at each occurrence identically or differently, selected from substituted or unsubstituted alkyl having 1 to 12 carbon atoms, or substituted or unsubstituted cycloalkyl having 3 to 12 ring carbon atoms.

According to an embodiment of the present disclosure, the substituent A is, at each occurrence identically or differently, selected from substituted or unsubstituted alkyl having 3 to 6 carbon atoms, or substituted or unsubstituted cycloalkyl having 3 to 6 ring carbon atoms.

According to an embodiment of the present disclosure, when the ligand Lₐ has the structure represented by Formula 1-1, at least one of R₂ and R₃ is the substituent A.

According to an embodiment of the present disclosure, when the ligand Lₐ has the structure represented by Formula 1-2, at least one of E₂ and E₃ is CRₑ and Rₑ is the substituent A; and/or at least one of F₁ and F₂ is CR_{f}, and R_{f} is the substituent A.

According to an embodiment of the present disclosure, when the ligand Lₐ has the structure represented by Formula 1-2, E₂ is CRₑ, and Rₑ is the substituent A; and/or F₂ is CR_{f}, and R_{f} is the substituent A.

According to an embodiment of the present disclosure, L_{b} and L_{c} are, at each occurrence identically or differently, selected from a structure represented by any one of the group consisting of the following:

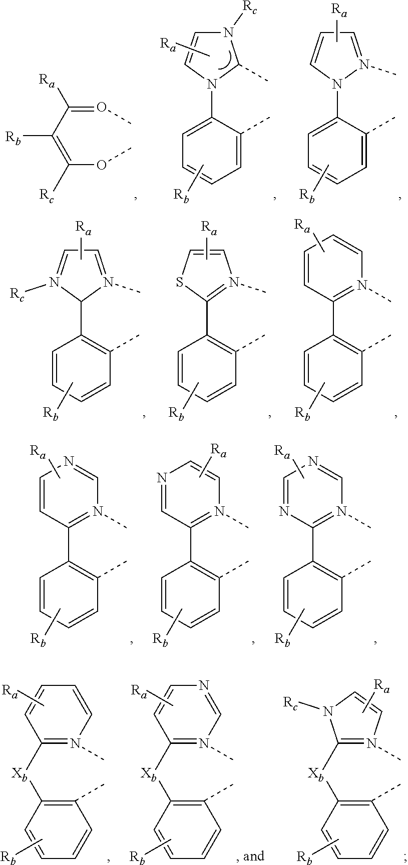

wherein
X_{b} is, at each occurrence identically or differently, selected from the group consisting of O, S, Se, NR_{N1}, and CR_{C1}R_{C2};
Rₐ and R_{b} represent, at each occurrence identically or differently, mono-substitution, multiple substitutions or non-substitution;
Rₐ, R_{b}, R_{c}, R_{N1}, R_{N2}, R_{C1} and R_{C2} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalky 1 having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon 5 atoms, substituted or unsubstituted aryl having 6 to 30 carbon atoms, substituted or unsubstituted heteroaryl having 3 to 30 carbon atoms, substituted or unsubstituted alkylsityl having 3 to 20 carbon atoms, substituted or unsubstituted arylsilyl having 6 to 20 carbon atoms, substituted or unsubstituted alkylgemanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof; and
adjacent substituents Rₐ, R_{b}, R_{c}, R_{N1}, R_{C1} and R_{C2} can be optionally joined to form a ring.

Herein, the expression that “adjacent substituents Rₐ, R_{b}, R_{c}, R_{N1}, R_{C1} and R_{C2} can be optionally joined to form a ring” is intended to mean that any one or more of groups of adjacent substituents, such as two substituents Rₐ, two substituents R_{b}, substituents Rₐ and R_{b}, substituents Rₐ and Rₑ, substituents R_{b} and Rₑ, substituents Rₐ and R_{N1}, substituents R_{b} and R_{N1}, substituents Rₐ and R_{C1}, substituents Rₐ and R_{C2}, substiments R_{b} and R_{C1}, substituents R_{b} and R_{C2}, and substituents R_{C1} and R_{C2}, can be joined to form a ring. Apparently, it is also possible that none of these groups are joined to form a ring. For example, adjacent substituents Rₐ and R_{b} in

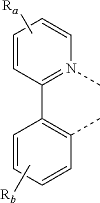

can be optionally joined to form a ring, and when Rₐ is optionally joined to form a ring,

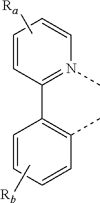

may form a structure of

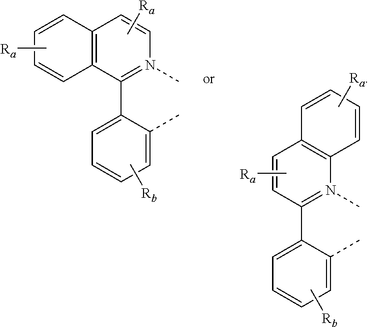

According to an embodiment of the present disclosure, the metal complex has a structure represented by Formula 2:

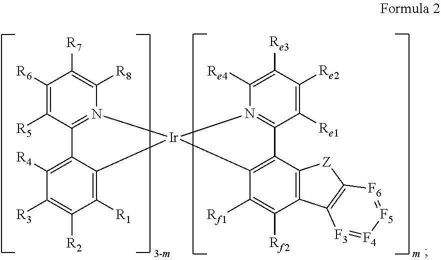

wherein
m is selected from 1, 2 or 3; preferably, m is selected from 1 or 2;
Z is selected from the group consisting of O, S, Se, NR′, CR′R′, SiR′R′, and GeR′R′, and when two R′ are present at the same time, the two R′ are identical or different;
F₃ to F₆ are, at each occurrence identically or differently, selected from CR_{f} or N;
at least one of R₂, R₃, Rₑ₂, and R_{f2} is the substituent A;
R₁ to R₈, R′, Rₑ₁ to Rₑ₄, R_{f1}, R_{f2}, and R_{f} are, at each occurrence identically or differently, selected firom the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alLoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
the substituent A is, at each occurrence identically or differently, selected from the group consisting of: substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, and combinations thereof;
adjacent substituents in R₁ to R₈ can be optionally joined to form a ring; and
adjacent substituents in R′, Rₑ to Rₑ₄, R_{f1}, R_{f2}, and R_{f} can be optionally joined to form a ring.

According to an embodiment of the present disclosure, Z is selected from the group consisting of O and S.

According to an embodiment of the present disclosure, Z is O.

According to an embodiment of the present disclosure, in Formula 2, F₃ to F₆ are, at each occurrence identically or diffcrently, selected from CR_{f}.

According to an embodiment of the present disclosure, in Formula 2, F₃ to F₆ are, at each occurrence identically or differently, selected from CR_{f}, and at least one R_{f} is a cyano group or fluorine; preferably, F₅ is CR_{f}, and R_{f} is a cyano group or fluorine.

According to an embodiment of the present disclosure, at least two of F₃ to F₆ are CR_{f}, one of R_{f} is a cyano group or fluorine, and at least one of the other R_{f} is selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgennanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof.

According to an embodiment of the present disclosure, at least two of to F₃ are CR_{f}, one of R_{f} is a cyano group or fluorine, and at least one of the other R_{f} is selected from the group: deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, a cyano group, a hydroxyl group, a sulfanyl group, and combinations thereof.

According to an embodiment of the present disclosure, at least two of F₃ to F₆ are CR_{f}, one of is a cyano group or fluorine, and at least one of the other R_{f} is selected from the group: deuterium, halogen, substituted or unsubstituted alkyl having 1 to 6 carbon atoms, substituted or unsubstituted cycloalkyl having, 3 to 6 ring carbon atoms, substituted or unsubstituted aryl having 6 to 12 carbon atoms, substituted or tmsubstituted heteroaryl having 3 to 12 carbon atoms, and combinations thereof.

According to another embodiment of the present disclosure, in Formula 2, F₃ to F₆ are, at each occurrence identically or differently, selected from CR_{f} or N: at least one of to F₆ is N, and preferably, F₆ is N.

According to an embodiment of the present disclosure, in Formula 2, R₂ is the substituent A.

According to an embodiment of the present disclosure,in Formula 2, R₃ is the substituent A.

According to an embodiment of c present disclosure, in Formula 2, R_{f2} is the substituent A.

According, to an embodiment of the present disclosure, in Formula 2, R₂ and Rₑ₂ are the substituent A, and R₂ and R_{f2} may be identical or different.

According to an embodiment of the present disclosure, in Formula 2, R₂ and R_{f2} are the substituent A, and R₂ and Rₑ₂ may be identical or different.

According to an embodiment of the present disclosure, in Formula 2, R₃ and Rₑ₂ are the substituent A, and R₃ and Rₑ₂ may be identical or different.

According to an embodiment of the present disclosure, in Formula 2, R₃ and R_{f2} are the substituent A, and R₃ and R_{f2} may be identical or different.

According to an embodiment of the present disclosure, in Formula 2, R_{f2} and Rₑ₂ are the substituent A, and R_{f2} and Rₑ₂ may be identical or different.

According to an embodiment of the present disclosure, in Formula 2, R₂, Rₑ₂, and R_{f2} are the substituent A, and R₂, Rₑ₂, and R_{f2} may be identical or different.

According to an embodiment of the present disclosure, in Formula 2, R₃, Rₑ₂, and R_{f2} are the substituent A, and R₃, Rₑ₂, and R_{f2} may be identical or different.

According, to an embodiment of the present disclosure, at least one or at least two of R₁ to R₈ is(are) selected from substituted or unsubstituted alkyl having 1 to 20 carbon atoms, substituted or unsubstituted cycloalkyl having 3 to 20 ring carbon atoms or combinations thereof, and the total number of carbon atoms in all of R₁ to R₄ and/or R₅ to R₈ is at least 4.

According to an embodiment of the present disclosure, at least one or at least two of R₅ to R₈ is(are) selected from substituted or unsubstituted alkyl having 1 to 20 carbon atoms, substituted or unsubstituted cycloalkyl having 3 to 20 ring carbon atoms or combinations thereof, and the total number of carbon atoms in all of the substituents R₅ to R₈ is at least 4.

According to an embodiment of the present disclosure, at least one or at least two of R₁ to R₄ is(are) selected from substituted or unsubstituted alkyl having 1 to 20 carbon atoms, substituted or unsubstituted cycloalkyl having 3 to 20 ring carbon atoms or combinations thereof, and the total number of carbon atoms in all of the substituents R₁ to R₄ is at least 4.

According to an embodiment of the present disclosure, at least one or at least two of the substituents R₁ to R₄ is(are) selected from substituted or unsubstituted alkyl having 1 to 20 carbon atoms, substituted or unsubstituted cycloalkyl having 3 to 20 ring carbon atoms or combinations thereof, and the total number of carbon atoms in all of the substituents R₁ to R₄ is at least 4; at the same time, at least one or at least two of the substituents R₅ to R₈ is(are) selected from substituted or unsubstituted alkyl having 1 to 20 carbon atoms, substituted or unsubstituted cycloalkyl having 3 to 20 ring carbon atoms or combinations thereof, and the total number of carbon atoms in all of the substituents R₅ to R₈ is at least 4.

According to an embodiment of the present disclosure, R₂ or R₃ is selected from substituted or unsubstituted alkyl having 1 to 20 carbon atoms, substituted or unsubstituted cycloalkyl having 3 to 20 ring carbon atoms or combinations thereof.

According to an embodiment of the present disclosure, R₂ or R₃ is selected from substituted or unsubstituted alkyl having 4 to 20 carbon atoms, substituted or unsubstituted cycloalkyl having 4 to 20 ring carbon atoms or combinations thereof.

According to an embodiment of the present disclosure, the metal M is, at each occurrence identically or differently, selected from the group consisting of Cu, Ag, Au, Ru, Rh, Pd, Os, Ir, and Pt,

According to an embodiment of the present disclosure, the metal M is, at each occurrence identically or differently, selected from Pt or Ir.

According to an embodiment of the present disclosure, the ductal complex is, at each occurrence identically or differently, selected from the group consisting of Metal complex 1 to Metal complex 50:

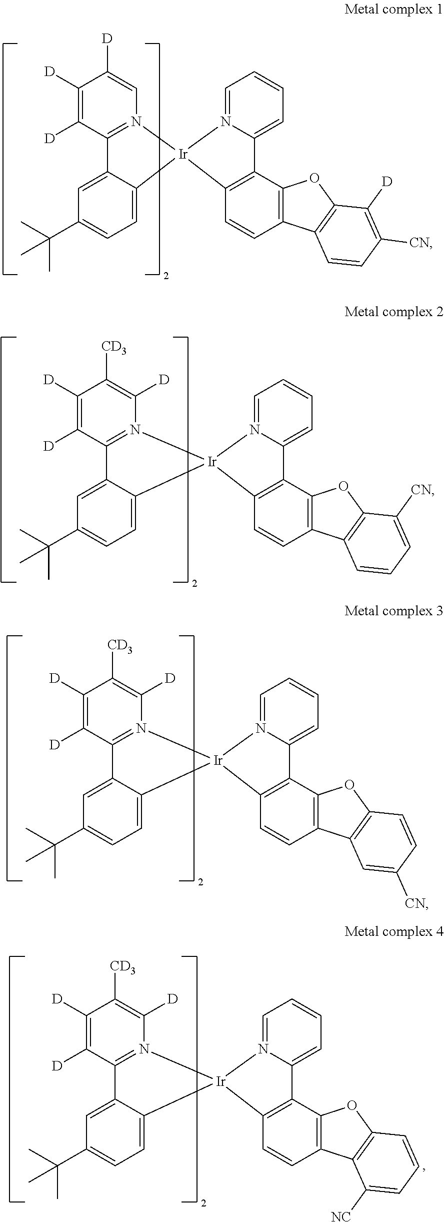

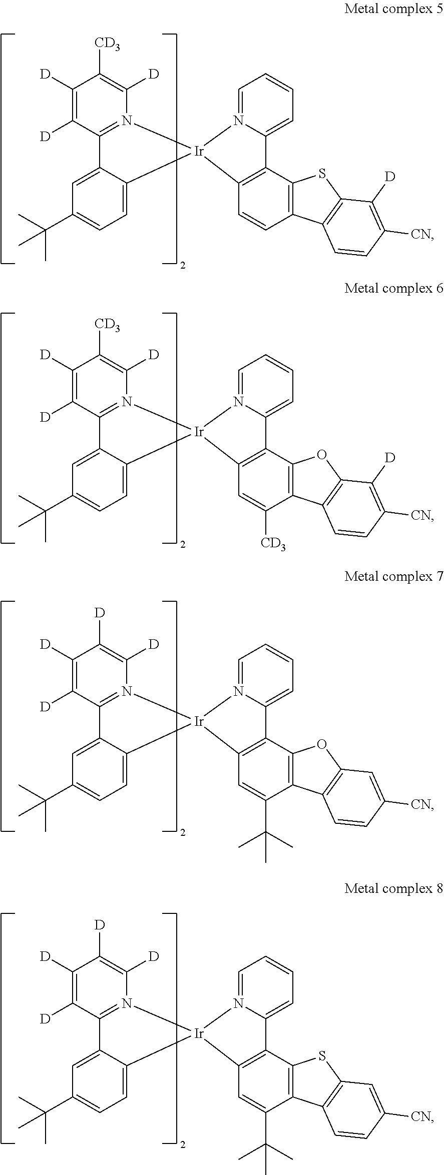

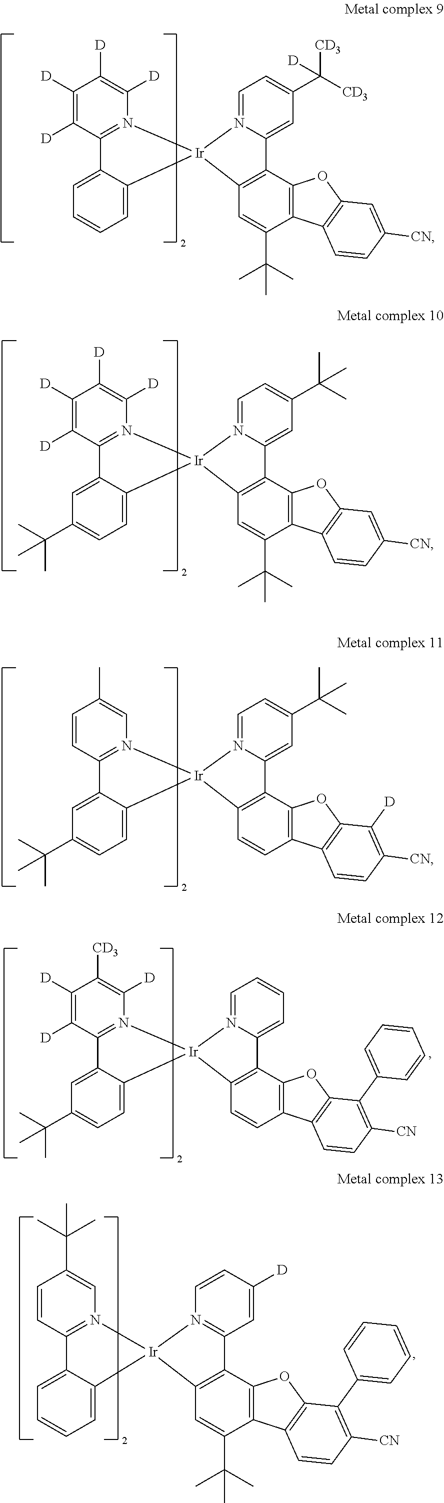

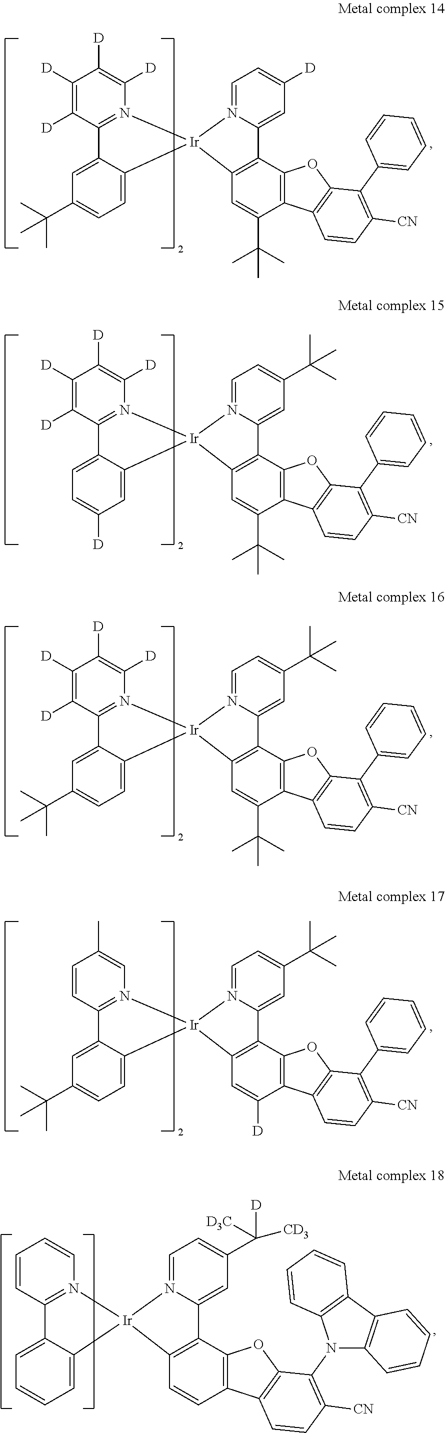

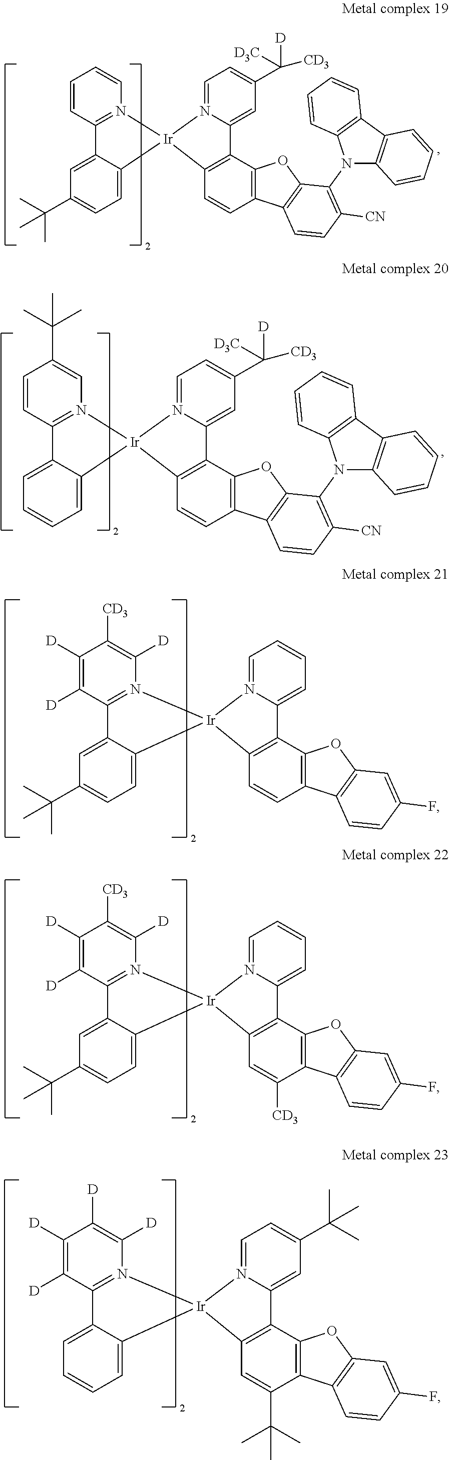

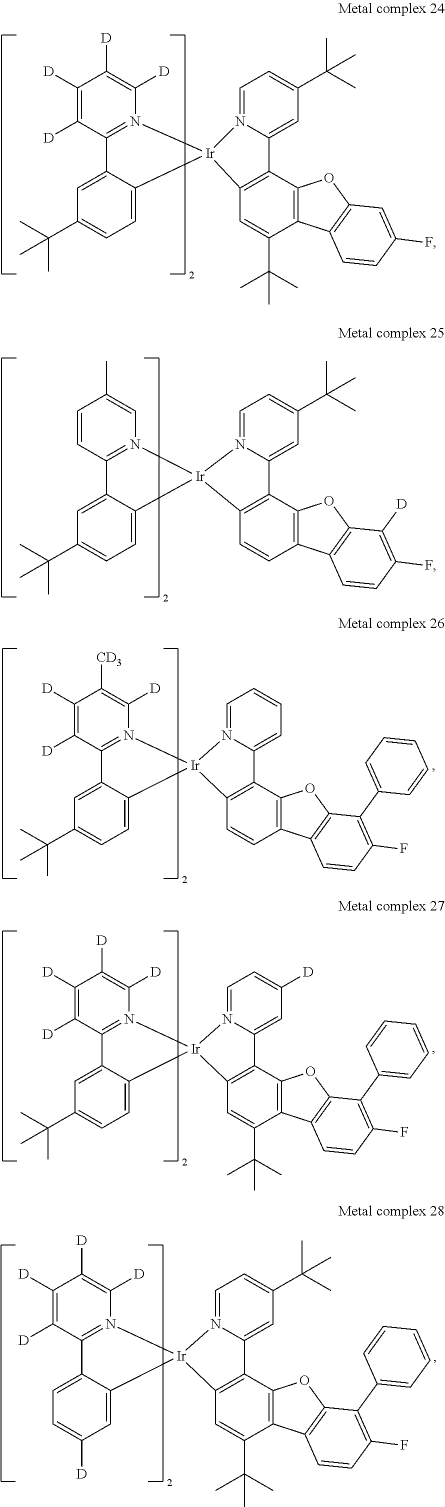

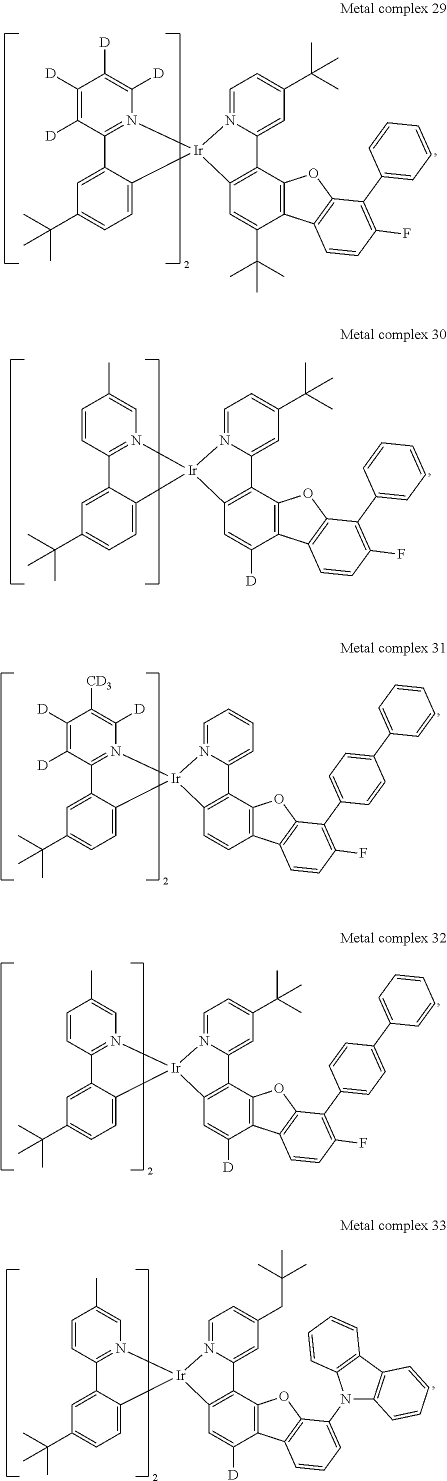

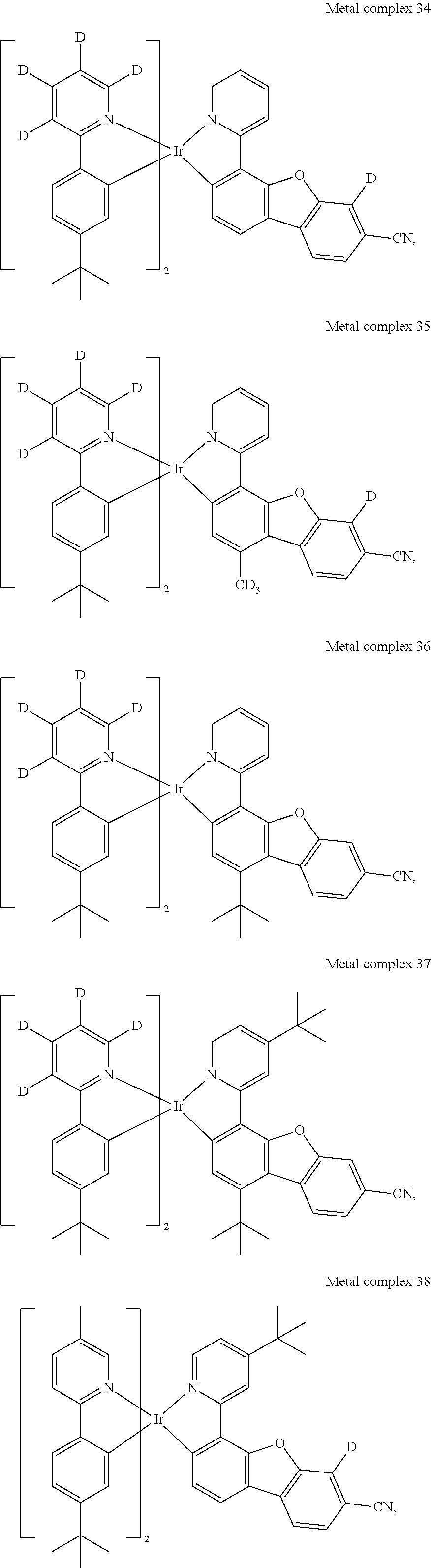

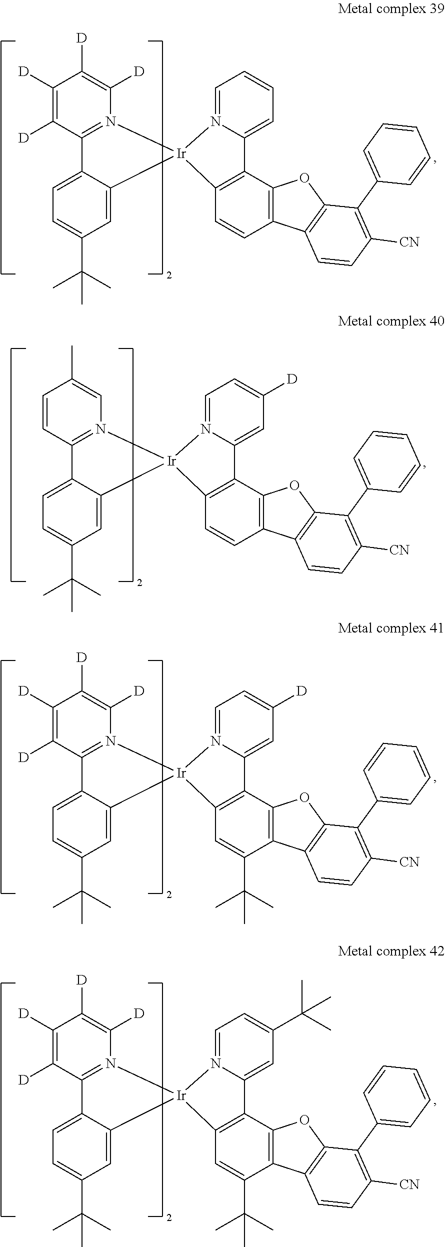

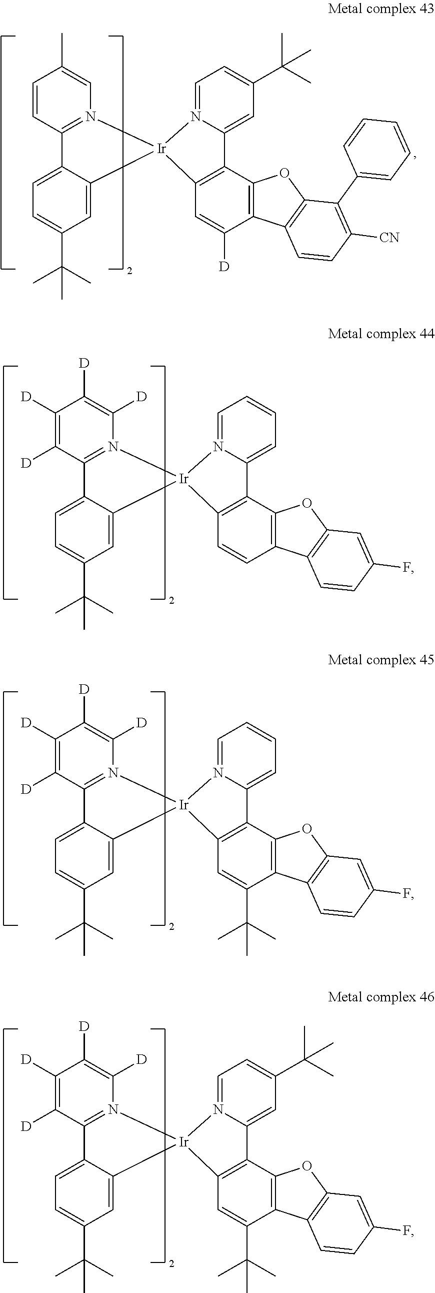

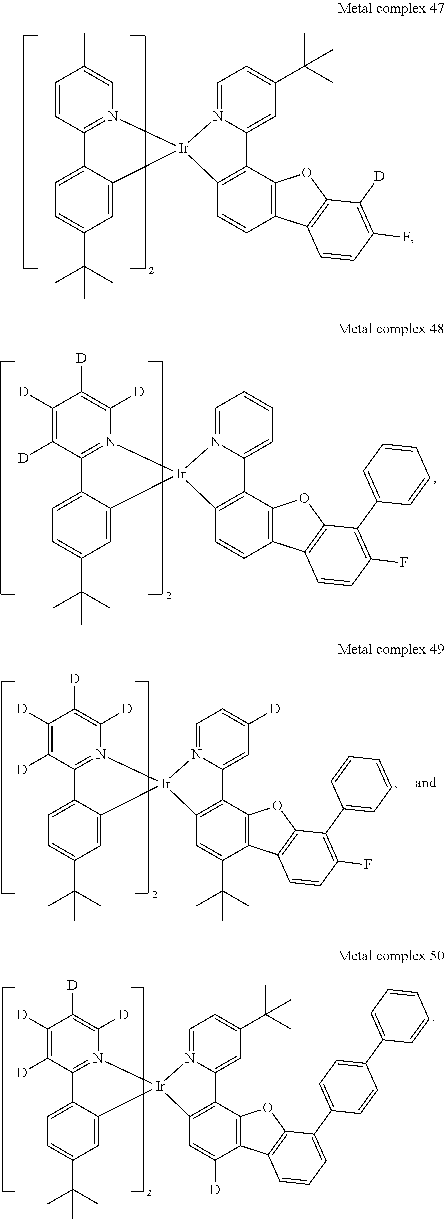

According to an embodiment of the present disclosure, hydrogens in Metal complex 1 to Metal complex 50 can be partially or fully substituted with deuterium.

According to another object of the present disclosure, an application of a metal complex in optoelectronic devices is further disclosed; and for the metal complex, reference is made to any one of the preceding embodiments,

According to an embodiment of the present disclosure, the metal complex in the electroluminescent device is doped in the first host compound and the second host compound, and a weight of the metal complex accounts for 1% to 30% of a total weight of the emissive layer.

According to an embodiment of the present disclosure, the metal complex in the electroluminescent device is doped in the first host compound and the second host compound, and the weight of the metal complex accounts for 3% to 13% of the total weight of the emissive layer.

According, to an embodiment of the present disclosure, the organic electroluminescent device further includes a hole injection layer. The hole injection layer may be a functional layer containing a single material or a functional layer containing a variety of materials, wherein the most commonly used ones among the variety of materials contained are hole transport materials doped with a certain proportion of p-type conductive doped material. The common p-type doped materials are as follows:

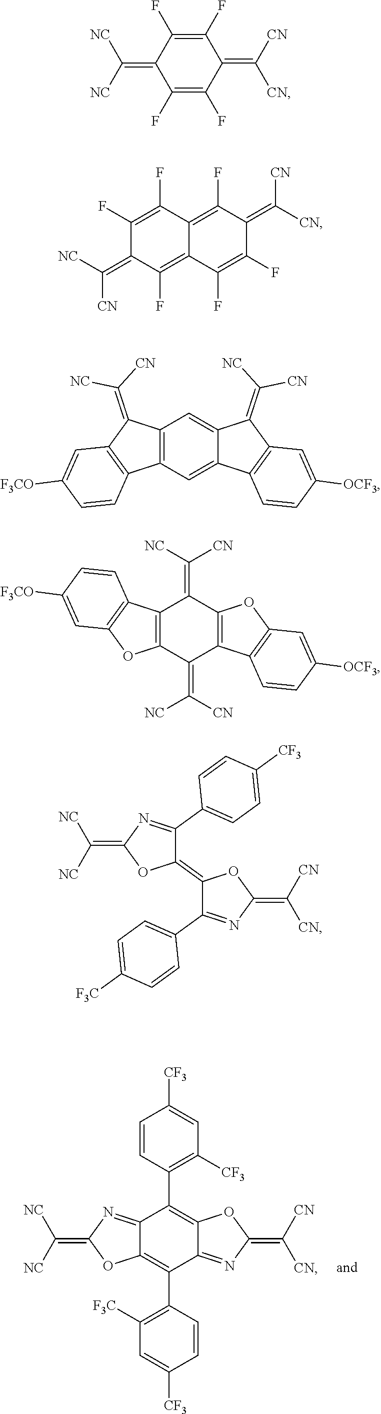

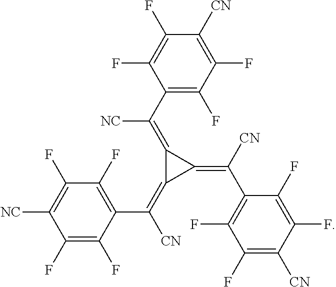 [SMILES: N#CC(=C1C(=C(C#N)c2c(F)c(F)c(C#N)c(F)c2F)C1=C(C#N)c1c(F)c(F)c(C#N)c(F)c1F)c1c(F)c(F)c(C#N)c(F)c1F]

According to an embodiment of the present disclosure, a display assembly is further disclosed. The display assembly includes the organic electroluminescent device described in any one of the preceding embodiments.

### Combination with Other Materials

The materials described in the present disclosure for a particular layer in an organic light-emitting device can be used in combination with various other materials present in the device. The combinations of these materials are described in more detail in U.S. Pat. App. No. 20160359122 at paragraphs 0132-0161, which is incorporated by reference herein in its entirety. The materials described or referred to the disclosure are non-limiting examples of materials that may be useful in combination with the compounds disclosed herein, and one of skill in the art can readily consult the literature to identify other materials that may be useful in combination.

The materials described herein as useful for a particular layer in an organic light-emitting device may be used in combination with a variety of other materials present in the device. For example, dopants disclosed herein may be used in combination with a wide variety of hosts, transport layers, blocking layers, injection layers, electrodes and other layers that may be present. The combination of these materials is described in detail in paragraphs 0080-0101 of U.S. Pat. App. No. 20150349273, which is incorporated by reference herein in its entirety. The materials described or referred to the disclosure are non-limiting examples of materials that may be useful in combination with the compounds disclosed herein, and one of skill in the art can readily consult the literature to identify other materials that may be useful in combination.

In the embodiments of material synthesis, all reactions were performed under nitrogen protection unless otherwise stated. All reaction solvents were anhydrous and used as received from commercial sources. Synthetic products were structurally confirmed and tested for properties using one or more conventional equipment in the art (including, but not limited to, nuclear magnetic resonance instrument produced by BRUKER, liquid chromatograph produced by SHIMADZU, liquid chromatograph-mass spectrometry produced by SHIMADZU, gas chromatograph-mass spectrometry produced by SHIMADZU, differential Scanning calorimeters produced by SHIMADZU, fluorescence spectrophotometer produced by SHANGHAI LENGGUANG TECH., electrochemical workstation produced by WUHAN CORRTEST, and sublimation apparatus produced by ANHUI BEQ, etc.) by methods well known to the persons skilled in the art. In the embodiments of the device, the characteristics of the device were also tested using conventional equipment in the art (including, but not limited to, evaporator produced by ANGSTROM ENGINEERING, optical testing system produced by SUZHOU FATAR, life testing system produced by SUZHOU FATAR, and ellipsometer produced by BEIJING ELLITOP, etc.) by methods well known to the persons skilled in the art. As the persons skilled in the art are aware of the above-mentioned equipment use, test methods and other related contents, the inherent data of the sample can be obtained with certainty and without influence, so the above related contents are not further described in this patent.

The electrochemical properties of compounds, including the highest occupied molecular orbital energy level and the lowest unoccupied molecular orbital energy level, are tested by cyclic voltammetry (CV). The test is conducted using an electrochemical workstation produced by WUHAN CORRTEST INSTRUMENTS CORP., LTD., Model No. CorrTest CS120, and using a three-electrode working system where a platinum disk electrode serves as a working electrode, an Ag/AgNO₃ electrode serves as a reference electrode, and a platinum wire electrode serves as an auxiliary electrode. Anhydrous DMF is used as a solvent, 0.1 mol/L tetrabutylammonium hexafluorophosphate is used as a supporting electrolyte, a compound to be tested is prepared into a solution of 10⁻³ mol/L, and nitrogen is introduced into the solution for 10 min for oxygen removal before the test. The parameters of the instrument are set as follows: the scan rate is 100 mV/s, the potential interval is 0.5 mV, the oxidation potential test window is 0 V to 1 V, and the reduction potential rest window is −1 V to −2.9 V. The energy levels of the metal complexes and part of the compounds used in the present application are shown in the following table.

| Compound | HOMO/eV | LUMO/eV | Compound | HOMO/eV | LUMO/eV |
|---|---|---|---|---|---|
| Metal complex 1 | −5.150 | −2.252 | GD1 | −5.199 | −2.301 |
| Metal complex 11 | −5.088 | −2.261 | GD2 | −5.166 | −2.285 |
| Metal complex 13 | −5.193 | −2.371 | GD3 | −5.199 | −2.396 |
| Metal complex 20 | −5.205 | −2.415 | GD4 | −5.213 | −2.427 |
| Metal complex 40 | −5.136 | −2.391 | GD5 | −5.171 | −2.385 |
| Metal complex 17 | −5.084 | −2.342 | | | |

The structures of the preceding metal complexes are as follows:

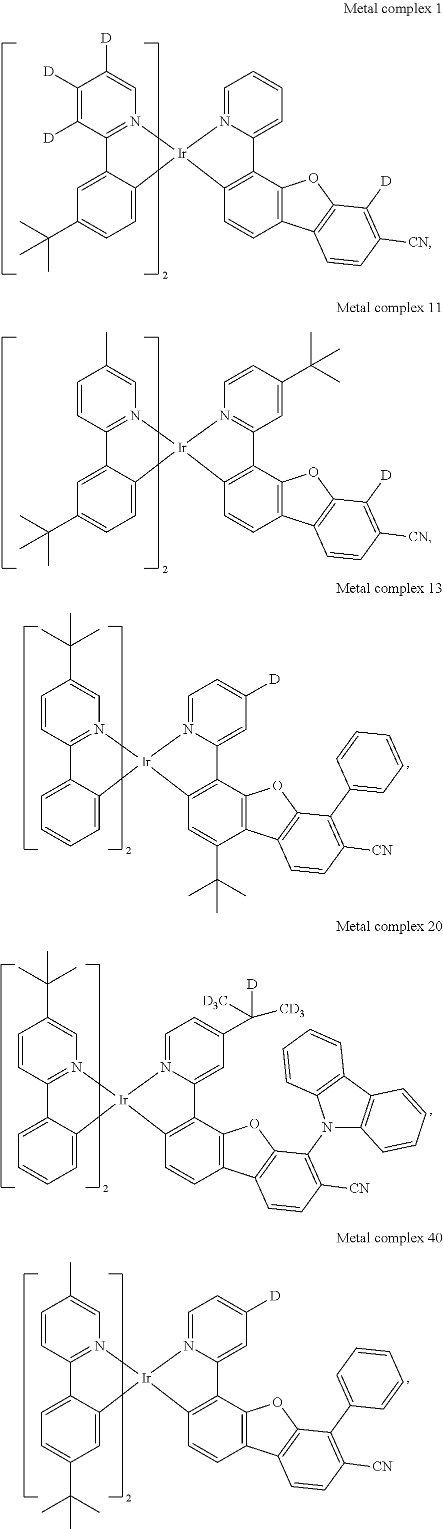

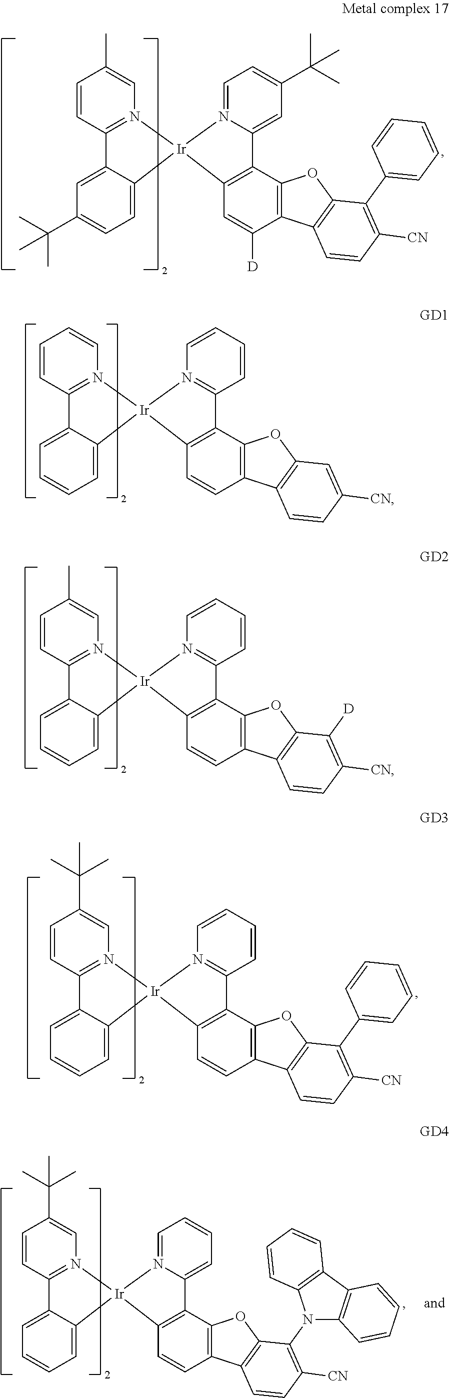

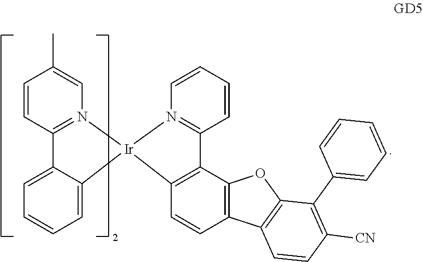

### Device Example 1

First, a glass substrate having an indium tin oxide (ITO) anode (whose sheet resistance was 14 to 20 Ω/sq and emission area was 0.04 cm²) with a thickness of 80 nm was cleaned and then treated with oxygen plasma and UV ozone. After the treatment, the substrate was dried in a glovebox to remove moisture. Then, the substrate was mounted on a substrate holder and placed in a vacuum chamber. The omanic layers specified below were sequentially deposited through vacuum thermal evaporation on the ITO anode at a rate of 0.2 to 2 Angstroms per second at a vacuum degree of about 10⁻⁸ torr. Compound HI was deposited as a hole injection layer (HIL). Compound HT was deposited as a hole transport layer (HTL). Compound H1 was deposited as an electron blocking layer (EBL). Metal Complex 1 of the present disclosure was doped in Compound H1 and Compound H2, and were co-deposited as an emissive layer (EML). On the EML, Compound HB was deposited as a hole blocking layer (HBL). On the HBL, Compound ET and 8-hydroxyguinolinolato-lithium (Lich) were co-deposited as an electron transport layer (ETL). Finally, 8-hydroxyquinolinolato-lithium (Liq) with a thickness of 1 nm was deposited as an electron injection layer, and Al with a thickness of 120 nm was deposited as a cathode. The device was transferred back to the glovebox and encapsulated with a glass lid and a moisture absorbent to complete the device.

### Device Example 2

The implementation in Device Example 2 as the same as the implementation in Device Example 1, except that in the emissive layer (EML), Metal Complex 1 of the present disclosure was replaced with Metal Complex 11.

Device Example 3

The implementation in Device Example 3 was the same as the implementation in Device Example 1, except that in the emissive layer (EML), Metal Complex 1 of the present disclosure was replaced with Metal Complex 13.

### Device Example 4

The implementation in Device Example 4 was the same as the implementation in Device Example 1, except that in the emissive layer (EML), Metal Complex 1 of the present disclosure was replaced with Metal Complex 20.

### Device Example 5

The implementation in Device Example 5 was the same as the implementation in Device Example 1, except that in the emissive layer (EML), Metal Complex 1 of the present disclosure was replaced with Metal Complex 40.

### Device Example 8

The implementation in Device Example 8 was the same as the implementation in Device Example 1, except that in the emissive layer (EML), Metal Complex 1 of the present disclosure was replaced with Metal Complex 17.

### Device Comparative Example 1

The implementation in Device Comparative Example 1 was the same as the implementation in Device. Example 1, except that in the emissive layer (EML), Metal Complex 1 of the present disclosure was replaced with metal complex GD1.

### Device Comparative Example 2

The implementation in Device Comparative Example 2 was the same as the implementation in Device Example 1, except that in the emissive layer (EML), Metal Complex 1 of the present disclosure was replaced with Metal complex GD2.

### Device Comparative Example 3

The implementation in Device Comparative Example. 3 was the same as the implementation in Device Example 1, except that in the emissive layer (EML), Metal Complex 1 of the present disclosure was replaced with Metal complex GD3.

### Device Comparative Example 4

The implementation in Device Comparative Example 4 was the same as the implementation in Device Example 1, except that in the emissive layer (EML), Metal Complex 1 of the present disclosure was replaced with Metal Complex GD4.

### Device Comparative Example 5

The implementation in Device Comparative Example 5 was the same as the implementation in Device Example 1, except that in the emissive layer (EML), Metal Complex 1 of the present disclosure was replaced with Metal Complex GD5.

Detailed structures and thicknesses of layers of the devices are shown in the following table. The layers using more than one material were obtained by doping different compounds at their mass ratios as recorded.

TABLE 1
Device structures in Examples 1 to 5, Example 8, and Comparative Examples 1 to 5

| Device ID | HIL | HTL | EBL | EML | HBL | ETL |
|---|---|---|---|---|---|---|
| Example 1 | Compound | Compound | Compound | Compound | Compound | Compound |
| | HI | HT | H1 | H1:Compound | HB | ET:Liq |
| | (100 Å) | (350 Å) | (50 Å) | H2:Metal | (50 Å) | (40:60) |
| | | | | complex 1 | | (350 Å) |
| | | | | (47:47:6) | | |
| | | | | (400 Å) | | |
| Example 2 | Compound | Compound | Compound | Compound | Compound | Compound |
| | HI | HT | H1 | H1:Compound | HB | ET:Liq |
| | (100 Å) | (350 Å) | (50 Å) | H2:Metal | (50 Å) | (40:60) |
| | | | | complex 11 | | (350 Å) |
| | | | | (47:47:6) | | |
| | | | | (400 Å) | | |
| Example 3 | Compound | Compound | Compound | Compound | Compound | Compound |
| | HI | HT | H1 | H1:Compound | HB | ET:Liq |
| | (100 Å) | (350 Å) | (50 Å) | H2:Metal | (50 Å) | (40:60) |
| | | | | complex 13 | | (350 Å) |
| | | | | (47:47:6) | | |
| | | | | (400 Å) | | |
| Example 4 | Compound | Compound | Compound | Compound | Compound | Compound |
| | HI | HT | H1 | H1:Compound | HB | ET:Liq |
| | (100 Å) | (350 Å) | (50 Å) | H2:Metal | (50 Å) | (40:60) |
| | | | | complex 20 | | (350 Å) |
| | | | | (47:47:6) | | |
| | | | | (400 Å) | | |
| Example 5 | Compound | Compound | Compound | Compound | Compound | Compound |
| | HI | HT | H1 | H1:Compound | HB | ET:Liq |
| | (100 Å) | (350 Å) | (50 Å) | H2:Metal | (50 Å) | (40:60) |
| | | | | complex 40 | | (350 Å) |
| | | | | (47:47:6) | | |
| | | | | (400 Å) | | |
| Example 8 | Compound | Compound | Compound | Compound | Compound | Compound |
| | HI | HT | H1 | H1:Compound | HB | ET:Liq |
| | (100 Å) | (350 Å) | (50 Å) | H2:Metal | (50 Å) | (40:60) |
| | | | | complex 17 | | (350 Å) |
| | | | | (47:47:6) | | |
| | | | | (400 Å) | | |
| Comparative | Compound | Compound | Compound | Compound | Compound | Compound |
| Example 1 | HI | HT | H1 | H1:Compound | HB | BT:Liq |
| | (100 Å) | (350 Å) | (50 Å) | H2:GD1 | (50 Å) | (40:60) |
| | | | | (47:47:6) | | (350 Å) |
| | | | | (400 Å) | | |
| Comparative | Compound | Compound | Compound | Compound | Compound | Compound |
| Example 2 | HI | HT | H1 | H1:Compound | HB | ET:Liq |
| | (100 Å) | (350 Å) | (50 Å) | H2:GD2 | (50 Å) | (40:60) |
| | | | | (47:47:6) | | (350 Å) |
| | | | | (400 Å) | | |
| Comparative | Compound | Compound | Compound | Compound | Compound | Compound |
| Example 3 | HI | HT | H1 | H1:Compound | HB | ET:Liq |
| | (100 Å) | (350 Å) | (50 Å) | H2:GD3 | (50 Å) | (40:60) |
| | | | | (47:47:6) | | (350 Å) |
| | | | | (400 Å) | | |
| Comparative | Compound | Compound | Compound | Compound | Compound | Compound |
| Example 4 | HI | HT | (50 Å) | H1:Compound | HB | ET:Liq |
| | (100 Å) | (350 Å) | | H2:GD4 | (50 Å) | (40:60) |
| | | | | (47:47:6) | | (350 Å) |
| | | | | (400 Å) | | |
| Comparative | Compound | Compound | Compound | Compound | Compound | Compound |
| Example 5 | HI | HT | H1 | H1:Compound | HB | BT:Liq |
| | (100 Å) | (350 Å) | (50 Å) | H2:GD5 | (50 Å) | (40:60) |
| | | | | (47:47:6) | | (350 Å) |
| | | | | (400 Å) | | |

The structures of the materials used iu the devices are as follows:

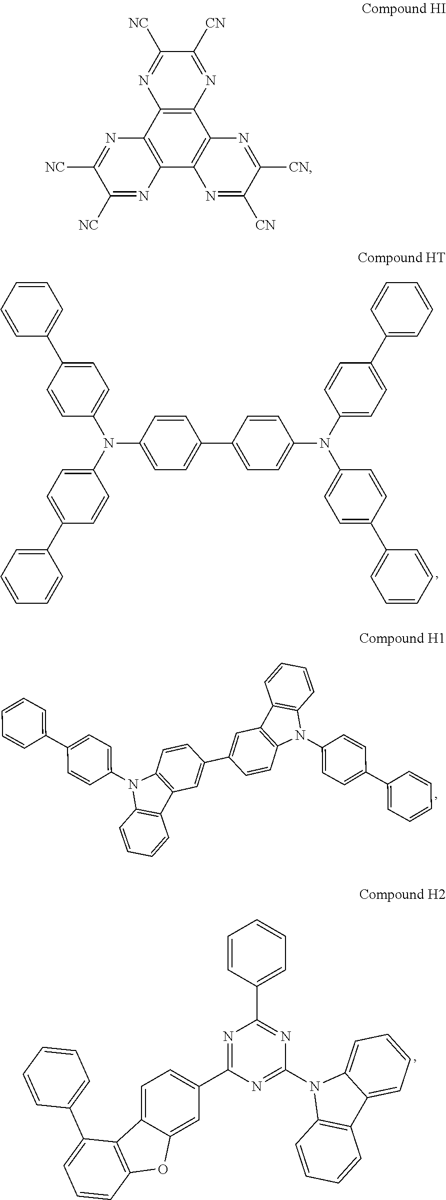 [SMILES: N#Cc1nc2c3nc(C#N)c(C#N)nc3c3nc(C#N)c(C#N)nc3c2nc1C#N ; c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(-c2ccc(-n3c4ccccc4c4cc(-c5ccc6c(c5)c5ccccc5n6-c5ccc(-c6ccccc6)cc5)ccc43)cc2)cc1 ; c1ccc(-c2nc(-c3ccc4c(c3)oc3cccc(-c5ccccc5)c34)nc(-n3c4ccccc4c4ccccc43)n2)cc1]

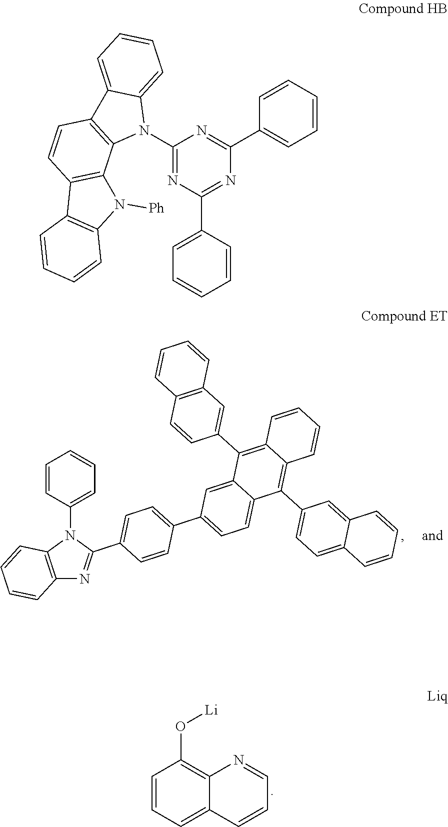

The capacitance of the devices was tested using an impedance analyzer (Model No. Keysight E4990A). A direct current bias voltage of −4 V to 5 V was applied to the electrodes at both ends of the device, a sinusoidal alternating current voltage signal of 100 mV was additionally applied, and the capacitance was separately tested at an alternating current voltage with a frequency of 500 Hz. The C-V curve of the device was measured and the initial voltage (Vₜ, and Vₜ₀), the voltage corresponding to the maximum capacitance (V_{Cmax}, and V_{Cmax0}), the geometric capacitance (C_{geo}, and C_{geo0}), the maximum capacitance (Cₘₐₓ, and Cₘₐₓ₀) and the difference between the maximum capacitance and the geometric capacitance (Cₘₐₓ−C_{geo0}, and Cₘₐₓ−C_{geo}) were obtained, and these data are recorded and shown in Table 2.

TABLE 2
Capacitance data in Examples 1 and 5, Example 8, and Comparative Examples 1 to 5

| | | | | | Difference | |
|---|---|---|---|---|---|---|
| | | | | | between | |
| | | | Voltage | | maximum | |
| | | | corresponding | | capacitance | |
| | Initial | Geometric | to maximum | Maximum | and geometric | |
| | voltage | capacitance | capacitance | capacitance | capacitance | ΔCₘₐₓ |
| Device ID | [V] | [nF] | [V] | [nF] | [nF] | [nF] |
| Example 1 | 2.66 | 1.29 | 3.43 | 1.60 | 0.31 | −0.17 |
| Comparative | 1.58 | 1.28 | 2.62 | 1.77 | 0.49 | |
| Example 1 | | | | | | |
| Example 2 | 0.50 | 1.27 | 2.21 | 2.78 | 1.51 | −0.47 |
| Comparative | 0.37 | 1.33 | 2.26 | 3.25 | 1.92 | |
| Example 2 | | | | | | |
| Example 3 | 0.50 | 1.27 | 3.02 | 3.05 | 1.78 | −0.54 |
| Comparative | −0.94 | 1.31 | 2.17 | 3.59 | 2.28 | |
| Example 3 | | | | | | |
| Example 4 | −0.76 | 1.28 | 2.26 | 3.44 | 2.16 | −0.24 |
| Comparative | −0.45 | 1.32 | 2.21 | 3.68 | 2.36 | |
| Example 4 | | | | | | |
| Example 5 | 2.21 | 1.31 | 3.25 | 1.72 | 0.41 | −1.66 |
| Comparative | −0.18 | 1.31 | 2.26 | 3.38 | 2.07 | |
| Example 5 | | | | | | |
| Example 8 | 0.05 | 1.25 | 2.21 | 2.79 | 1.54 | −0.53 |
| Comparative | −0.18 | 1.31 | 2.26 | 3.38 | 2.07 | |
| Example 5 | | | | | | |

As shown in Table 2, the difference between Device Example 2 and Device Comparative Example 2 and the difference between Device Example 4 and Device Comparative Example 4 are only that the metal complexes in the emissive layers were different, and the metal complexes differed in only that whether the ligand included a substituent A; in addition to the substituent A, the difference between Example 1 and Comparative Example 1, the difference between Example 3 and Comparative Example 3, the difference between Example 5 and Comparative Example 5, the difference between Example 8 and Comparative Example 5 are that part of hydrogens in the metal complex was replaced with deuterium, however, the difference between hydrogen and deuterium in the metal complex had a negligible effect on the capacitance of the device, so the difference in the capacitance in the examples and comparative examples was caused by the substituent A.

As can be seen from the one-to-one comparison between Examples and Comparative Examples in Table 2, the capacitance in each of Examples was significantly reduced, compared with the capacitance in the corresponding comparative example, which decreased by 0.17 nF, 0.47 nF. 0.54 nF, 0.24 nF, 1.66 nF, and 0.53 nF, respectively, indicating that the introduction of the substituent A produces an excellent effect on the reduction of the capacitance performance of the device.

### Device Example 6

The implementation in Device Example 6 was the same as the implementation in Device Example 3, except that in the emissive layer (EML), the ratio of Compound H1, Compound H2 to Metal complex 13 was 56:38:6.

### Device Example 7

The implementation in Device Example 7 was the same as the implementation in Device Example 6, except that in the emissive layer (EML), Metal Complex 13 of the present disclosure was replaced with Metal Complex 20.

Device Comparative Example 6

The implementation in Device Comparative Example 6 was the same as the implementation in Device Example 6, except that in the emissive layer (EML), Metal Complex 13 of the present disclosure was replaced with Metal complex GD3.

### Device Comparative Example 7

The implementation in Device Comparative Example 7 was the same as the implementation in Device Example 7, except that in the emissive layer (EML), Metal Complex 20 of the present disclosure was replaced with Metal Complex GD4.

TABLE 3
Device structures in Examples 6 to 7 and Comparative Examples 6 to 7

| Device ID | HIL | HTL | EBL | BML | HBL | ETL |
|---|---|---|---|---|---|---|
| Example 6 | Compound | Compound | Compound | Compound | Compound | Compound |
| | HI | HT | H1 | H1:Compound | HB | ET:Liq |
| | (100 Å) | (350 Å) | (50 Å) | H2:Metal | (50 Å) | (40:60) |
| | | | | complex 13 | | (350 Å) |
| | | | | (56:38:6) | | |
| | | | | (400 Å) | | |
| Example 7 | Compound | Compound | Compound | Compound | Compound | Compound |
| | HI | HT | H1 | H1:Compound | HB | BT:Liq |
| | (100 Å) | (350 Å) | (50 Å) | H2:Metal | (50 Å) | (40:60) |
| | | | | complex 20 | | (350 Å) |
| | | | | (56:38:6) | | |
| | | | | (400 Å) | | |
| Comparative | Compound | Compound | Compound | Compound | Compound | Compound |
| Example 6 | HI | HT | H1 | H1:Compound | HB | ET:Liq |
| | (100 Å) | (350 Å) | (50 Å) | H2:Metal | (50 Å) | (40:60) |
| | | | | complex GD3 | | (350 Å) |
| | | | | (56:38:6) | | |
| | | | | (400 Å) | | |
| Comparative | Compound | Compound | Compound | Compound | Compound | Compound |
| Example 7 | HI | HT | H1 | H1:Compound | HB | ET:Liq |
| | (100 Å) | (350 Å) | (50 Å) | H2:Metal | (50 Å) | 40:60) |
| | | | | complex GD4 | | (350 Å) |
| | | | | (56:38:6) | | |
| | | | | (400 Å) | | |

The IVL properties of the devices were measured. The external quantum efficiency (EQE) of the devices was measured at 15 mA/cm² and are recorded in Table 4.

TABLE 4
Device data of Examples 6 to 7 and Comparative Examples 6 to 7

| Device ID | EQE (%) |
|---|---|
| Example 6 | 23.17 |
| Example 7 | 24.60 |
| Comparative Example 6 | 22.78 |
| Comparative Example 7 | 24.55 |

As can be seen from the data in Table 4, compared with the comparative example devices prepared with the metal complex that does not include a substituent A, the example devices prepared with the metal complex including a substituent A still maintained excellent device performance and maintained an EQE level comparable to the EQE level in the comparative examples.

As can be seen from the preceding results, the organic electroluminescent device including a metal complex having a substituent A capable of reducing the maximum capacitance in the device can improve the response time and refresh frequency of an OLED display device at a low grayscale. In another aspect, the substituent A can cause a decrease in the maximum capacitance of the device, and the device prepared with the metal complex including the substituent A can still maintain excellent device performance compared with the devices prepared with the metal complexes that do not include the substituent A.

It should be understood that various embodiments described herein are merely examples and not intended to limit the scope of the present disclosure. Therefore, it is apparent to the persons skilled in the art that the present disclosure as claimed may include variations from specific embodiments and preferred embodiments described herein. Many of materials and structures described herein may be substituted with other materials and structures without departing from the spirit of the present disclosure. It should be understood that various theories as to why the present disclosure works are not intended to be limitative.

What is claimed is:

1. An organic electroluminescent device, comprising a cathode, an anode, and an organic layer disposed between the cathode and the anode;
wherein the organic layer comprises a metal complex, and the metal complex comprises a metal M and at least one C\hat{ }N bidentate ligand Lₐ coordinated to the metal M;
the metal M is selected from a metal with a relative atomic mass greater than 40;
when two or more ligands Lₐ are present at the same time, the two or more ligands may be identical or different;
at least one ligand Lₐ comprises at least one substituent A;
the substituent A is, at each occurrence identically or differently, selected from a substituted Or unsubstituted non-aromatic group having 1 to 20 carbon atoms;
when two or more substituents A are present at the same time, the two or more substituents A may be identical or different; and
the capacitance characteristics of the metal complex in an electroluminescent device satisfy:
at 500 Hz, a maximum capacitance of the electroluminescent device is Cₘₐₓ; and
at 500 Hz, a change in the maximum capacitance caused by the substituent A is ΔCₘₐₓ≤−0.12 nF.

2. The organic electroluminescent device of claim 1, wherein at 500 Hz, the change in the maximum capacitance caused by the substituent A is ΔCₘₐₓ≤−0.17 nF;
preferably, at 500 Hz, the change in the maximum capacitance caused by the substituent A is ΔCₘₐₓ=−0.19 nF; and
more preferably, at 500 Hz, the change in the maximum capacitance caused by the substituent A is ΔCₘₐₓ≤−0.24 nF.

3. The organic electroluminescein device of claim 1, wherein at 500 Hz, 1.5 nF≤Cₘₐₓ≤6.00 nF, and in the electroluminescent device, 0.5 nF≤Cₘₐₓ≤5.0 nF;
preferably, at 500 Hz, 2.0 nF≤Cₘₐₓ₀≤6.00 nF, and in the electroluminescent device, 0.5 nF≤Cₘₐₓ≤4.0 nF; and
more preferably, at 500 Hz, 2.5 nF≤Cₘₐₓ₀≤6.00 F, and in the electroluminescent device, 0.5 nF≤Cₘₐₓ≤3.5 nF.

4. The organic electrolutninescent device of claim 1, wherein at 500 Hz, 0.42 nF≤Cₘₐₓ₀−C_{geo0}≤3.80 nF, and in the electroluminescent device, 0.30 nF≤Cₘₐₓ-C_{geo}≤3.68 nF;
preferably, at 500 Hz, 1.30 nF≤Cₘₐₓ₀−C_{geo0}≤3.80 nF, and in the electroluminescent device, 0.30 nF≤Cₘₐₓ−C_{geo}≤2.80 nF; and
more preferably, at 500 Hz. 1.80 nF≤Cₘₐₓ₀−C_{geo0}≤3.80 nF, and in the electroluminescent device, 0.30 nF≤Cₘₐₓ−C_{geo}≤2.30 nF.

5. The organic electroluminescent device of claim 1, wherein at 500 Hz, an initial voltage Vₜ of the electroluminescent device satisfies: −4.0 V≤V_{t≤}5.0 V;
preferably, at 500 Hz, the initial voltage Vₜ of the electroluminescent device satisfies: −2 V≤Vₜ≤4.0 V; and
more preferably, at 500 Hz, the initial voltage Vₜ of the electroluminescent device satisfies: −1.0 V≤Vₜ≤3.0 V.

6. The organic electroluminescent device of claim 1, wherein at 500 Hz, when the capacitance of the electroluminescent device reaches the maximum value Cₘₐₓ, a corresponding voltage V_{Cmax} satisfies: 1.0 V≤V_{Cmax}≤6.0 V;
preferably, at 500 Hz, when the capacitance of the electroluminescent device reaches the maximum value Cₘₐₓ, the corresponding voltage V_{Cmax} satisfies: 1.5 V≤V_{Cmax}≤5.0 V; and
more preferably, at 500 Hz, when the capacitance of the electroluminescent device reach the maximum value Cₘₐₓ, the corresponding voltage V_{Cmax} satisfies: 2.0 V≤V_{Cmax}≤4.0 V.

7. The organic electroluminescent device of claim 1, wherein a highest occupied molecular orbital energy level (E_{HOMO}) of the metal complex is less than or equal to −5.05 eV;
preferably, the highest occupied molecular orbital energy level of the metal complex is less than or equal to −5.10 eV; and
more preferably, the highest occupied molecular orbital energy level of the metal complex is less than or equal to −5.15 eV.

8. The organic electroluminescent device of claim 1, wherein a lowest unoccupied molecular orbital energy level (E_{LUMO}) of the metal complex is less than or equal to −2.10 eV;
preferably, the lowest unoccupied molecular orbital energy level of the metal complex is less than or equal to −2.1.5 eV; and
more preferably, the lowest unoccupied molecular orbital energy level of the metal complex is less than or equal to −2.20 eV.

9. The organic electroluminescent device of claims 1, wherein the organic layer comprising the metal complex is an emissive layer.

10. The organic electroluminescent device of claim 9, wherein the emissive layer further comprises a first host compound;
preferably, the emissive layer further comprises a second host compound; and
more preferably, the first host compound and/or the second host compound comprise at least one chemical group selected from the group consisting of: benzene, pyridine, pyrimidine, triazine, carbazole, azacatbazole, indolocarbazole, dibenzothiophene, azadibenzothiophene, dibenzofuran, azadiberizofuran dibenzoselenophene, triphenylene, azatriphenylene, fluorene silafluorene, naphthalene, quinoline, isoquinoline, quinazoline, quinoxaline, phenanthrene, azaphenanthrene, and combinations thereof.

11. The organic electroluminescent device of claim 10, wherein the metal complex is doped in the first host compound and the second host compound, and a weight of the metal complex accounts for 1% to 30% of a total weight of the organic layer; and
preferably, the metal complex is doped in the first host compound and the second host compound, and the weight of the metal complex accounts for 3% to 13% of the total weight of the manic layer.

12. The organic electroiuminescent device of claim 1, wherein the metal complex has a general formula of M(Lₐ)ₘ(L_{b})ₙ(L_{c})_{q};
Lₐ, L_{b}, and L_{c} are a first ligand, a second ligand and a third ligand coordinated to the metal M, respectively, and Lₐ, and L_{b}, and L_{c} are identical or different; wherein Lₐ, and L_{b}, and L_{c} can be optionally, oined to form a tetradentatc ligand or a multidentate ligand;
m is selected from 1, 2 or 3, n is selected from 0, 1 or 2, q is selected from 0, 1 or 2, and m+n+q equals an oxidation state of the metal M; when m is greater than or equal to 2, a plurality of Lₐ are identical or different; when n is equal to 2, two L_{b} are identical or different; when q is equal to 2, two L_{c} are identical or different;
Lₐ is, at each occurrence identically or differently, selected from a C\hat{ }N bidentate ligand;
the metal M is selected from a metal with a relative atomic mass greater than 40;
Lₐ has a structure of E-F,
wherein E is, at each occurrence identically or differently, selected from a substituted or unsubstituted heteroaromatic ring having 5 to 30 ring atoms, the heteroaromatic ring comprises at least one nitrogen atom, and E is bonded to the metal through the nitrogen atom in the heteroaromatic ring to form a metal-nitrogen bond or a metal-G-nitrogen bond;
F is, at each occurrence identically or differently, selected from a substituted or unsubstituted aromatic ring having 6 to 30 ring atoms, a substituted or unsubstituted heteroaromatic ring having 5 to 30 ring atoms or combinations thereof, and the ring F is bonded to the metal through the carbon atom in the aromatic ring or the heteroaromatic ring to form a metal-carbon bond or a metal-G-carbon bond;
F has at least one substituent A, and/or when F is a multi-membered fused ring, E has at least one substituent A;
when two or more substituents A are present at the same time, the two or more substituents A are identical or different;
the substituent A is, at each occurrence identically or differently, selected troin a substituted or unsubstituted non-aromatic group having 1 to 20 carbon atoms;
G is, at each occurrence identically or differently, selected from O or S; and
adjacent substituents can be optionally joined to form a ring; and
Lₐ and L_{c} are, at each occurrence identically or differently, selected from a monoanionic bidentate ligand.

13. The organic eleetroluminescenee device of claim 1, wherein the metal M is, at each occurrence identically or differently, selected from the group consisting of Cu, Ag, Ali, Ru, Rh, Pd, Os, Ir, and Pt; and
preferably, the metal M is, at each occurrence identically or differently, selected from Pt or Ir.

14. A display assembly, comprising, the ormnic electroluminescent device of claim 1.

15. A metal complex has a general formula of M(Lₐ)ₘ(L_{b})ₙ(L_{c})_{q}, wherein Lₐ, and L_{b}, and L_{c} are a first ligand, a second ligand and a third ligand coordinated to a metal M, respectively, and Lₐ, and L_{b}, and L_{c} are identical or different; wherein Lₐ, and L_{b}, and L_{c} can be optionally joined to form a tetradentate ligand or a multidentate ligand;
m is selected from 1, 2 or 3, n is selected from 0, 1 or 2, q is selected from 0, 1 or 2, and m+n+q equals an oxidation state of the metal M; when in is greater than or equal to 2, a plurality of Lₐ are identical or different; when n is equal to 2, two L_{b} are identical or different; when q is equal to 2, two L_{c} are identical or different;
Lₐ is, at each occurrence identically or differently, selected from a C\hat{ }N bidentate ligand;
the metal M is selected from a metal with a relative atomic mass greater than 40;
Lₐ has a structure of E-F.
wherein E is, at each occurrence identically or differently, selected from a substituted or unsubstituted heteroaromatic ring having 5 to 30 ring atoms, the heteroaromatic ring includes at least one nitrogen atom, and F is bonded to the metal through the nitrogen atom in the heteroaromatic ring to form a metal-nitrogen bond or a metal-G-nitrotten bond;
F is, at each occurrence identically or differently, selected from a substituted or unsubstituted aromatic ring having 6 to 30 ring atoms, a substituted or unsubstituted heteroaromatic, ring having 5 to 30 ring atoms or combinations thereof, and the ring F is bonded to the metal through the carbon atom in the aromatic ring or the heteroaromatic ring to form a metal-carbon bond or a metal-G-carbon bond;
F has at least one substituent A, and/or when F is a multi-membered fused ring, E has at least one substituent A;
when two or more substituents A are present at the same time, the two or more substituents A are identical or different;
the substituent A is, at each occurrence identically or differently, selected from a substituted or unsubstituted non-aromatic group having 1 to 20 carbon atoms;
G is, at each occurrence identically or differently, selected from O or S;
adjacent substituents can be optionally joined to form a ring; and
the substituent A can be optionally joined to other substituents in the ligand Lₐ to form a L_{b} and L_{c} are, at each occurrence identically or differently, selected from a monoanionic bidentate ligand; and
the metal complex in an electroluminescent device satisfies;
at 500 Hz, a maximum capacitance of the electroluminescent device is Cₘₐₓ; and
at 500 Hz, a change in the maximum capacitance caused by the substituent A is ΔCₘₐₓ≤−0.12 nF.

16. The metal complex of claim 15, the F is a multi-membered fused ring, the substituent A is on a ring in the F which is directly bonded to the metal, or the substituent A is on the E.
